(19) United States
(12) Patent Application Publication
(10) Pub. No.: US 2026/0334030 A1
(43) Pub. Date: Oct. 22, 2026

(54) DISPLAY PANEL AND DISPLAY DEVICE

(71) Applicant: Wuhan Tianma Microelectronics Co., Ltd., Wuhan (CN)

(72) Inventors: Wei Cheng, Wuhan (CN); Xue Li, Wuhan (CN)

(73) Assignee: Wuhan Tianma Microelectronics Co., Ltd., Wuhan (CN)

(21) Appl. No.: 19/693,929

(22) Filed: Jun. 1, 2026

(30) Foreign Application Priority Data
Nov. 10, 2025 (CN) 202511632772.1

(51) Int. Cl. H10K 59/131; H10K 59/00; H10K 59/126; H10K 102/00

(52) U.S. Cl. CPC H10K 59/131; H10K 59/126; H10K 59/771; H10K 2102/311

(57) ABSTRACT

A display panel includes a display region and a non-display region located on at least one side of the display region and including a bending region and a first via transition region located on a side of the bending region facing the display region. The display panel further includes a substrate and a signal routing located on a side of the substrate and including signal transmission lines and signal connection lines arranged in different layers. The signal connection lines are located on a side of the signal transmission lines facing away from the substrate, and are electrically connected to the signal connection lines through a connection via in the first via transition region. The display panel further includes a first shielding structure located on a side of the signal connection lines facing away from the substrate and at least partially overlaps with the first via transition region.

### CROSS-REFERENCE TO RELATED APPLICATION(S)

This application claims priority to Chinese Patent Application No. 202511632772.1 filed Nov. 10, 2025, the disclosure of which is incorporated herein by reference in its entirety.

### TECHNICAL FIELD

The present application relates to the field of display technology and, in particular, to a display panel and a display device.

### BACKGROUND

With the advancement of display panel technology, the display requirements for display panels have become increasingly stringent, leading to greater complexity of signal routing in display panels. As the density of signal wirings in the bonding region of a display panel increases, the electric field intensity correspondingly increases. Under the effect of the electric field, corrosion of signal wirings at transition via locations in the bonding region is exacerbated, which in turn is likely to cause display abnormalities.

### SUMMARY

Embodiments of the present application provide a display panel and a display device. By arranging a first shielding structure to be located on a side of signal connection lines facing away from a substrate and the first shielding structure to at least partially overlap with a first via transition region, the reactive ions are blocked from reaching the first via transition region through the first shielding structure, thereby alleviating the corrosion in the first via transition region.

In a first aspect, the embodiments of the present application provide a display panel. The display panel includes a display region and a non-display region, and the non-display region is located on at least one side of the display region.

The non-display region includes a bending region and a first via transition region, and the first via transition region is located on a side of the bending region facing the display region.

The display panel further includes a substrate and a signal routing located on a side of the substrate. The signal routing includes signal transmission lines and signal connection lines arranged in different layers, and the signal connection lines are located on a side of the signal transmission lines facing away from the substrate. The signal transmission lines and the signal connection lines are electrically connected through at least one connection via in the first via transition region.

The display panel further includes a first shielding structure. The first shielding structure is located on a side of the signal connection lines facing away from the substrate, and the first shielding structure at least partially overlaps with the first via transition region.

In a second aspect, the embodiments of the present application provide a display panel. The display panel includes a display region and a non-display region, and the non-display region is located on at least one side of the display region.

The non-display region includes a bending region and a first via transition region, and the first via transition region is located on a side of the bending region facing the display region.

The display panel further includes a substrate and a signal routing located on a side of the substrate. The signal routing includes signal transmission lines and signal connection lines arranged in different layers, and the signal connection lines are located on a side of the signal transmission lines facing away from the substrate. The signal transmission lines and the signal connection lines are electrically connected through at least one connection via in the first via transition region.

The display panel further includes a first shielding structure. The first shielding structure is located on a side of the signal connection lines facing away from the substrate, and the first shielding structure at least partially overlaps with the first via transition region.

The first shielding structure includes a second shielding layer.

The display panel further includes a pixel defining layer, and the second shielding layer is located on a side of the pixel defining layer facing away from the substrate.

In a third aspect, the embodiments of the present application provide a display panel. The display panel includes a display region and a non-display region, and the non-display region is located on at least one side of the display region.

The non-display region includes a bending region and a first via transition region, and the first via transition region is located on a side of the bending region facing the display region.

The display panel further includes a substrate and a signal routing located on a side of the substrate. The signal routing includes signal transmission lines and signal connection lines arranged in different layers, and the signal connection lines are located on a side of the signal transmission lines facing away from the substrate. The signal transmission lines and the signal connection lines are electrically connected through at least one connection via in the first via transition region.

The display panel further includes a silicon-nitride-based inorganic layer located on a side of the signal connection lines facing away from the substrate. The silicon-nitride-based inorganic layer is staggered from the first via transition region in the thickness direction of the display panel.

In a fourth aspect, the embodiments of the present application further provide a display device. The display device includes a display panel.

The display panel includes a display region and a non-display region, and the non-display region is located on at least one side of the display region.

The non-display region includes a bending region and a first via transition region, and the first via transition region is located on a side of the bending region facing the display region.

The display panel further includes a substrate and a signal routing located on a side of the substrate. The signal routing includes signal transmission lines and signal connection lines arranged in different layers, and the signal connection lines are located on a side of the signal transmission lines facing away from the substrate. The signal transmission lines and the signal connection lines are electrically connected through at least one connection via in the first via transition region.

The display panel further includes a first shielding structure. The first shielding structure is located on a side of the signal connection lines facing away from the substrate, and the first shielding structure at least partially overlaps with the first via transition region.

In a fifth aspect, the embodiments of the present application further provide a display device. The display device includes a display panel.

The display panel includes a display region and a non-display region, and the non-display region is located on at least one side of the display region.

The non-display region includes a bending region and a first via transition region, and the first via transition region is located on a side of the bending region facing the display region.

The display panel further includes a substrate and a signal routing located on a side of the substrate. The signal routing includes signal transmission lines and signal connection lines arranged in different layers, and the signal connection lines are located on a side of the signal transmission lines facing away from the substrate. The signal transmission lines and the signal connection lines are electrically connected through at least one connection via in the first via transition region.

The display panel further includes a first shielding structure. The first shielding structure is located on a side of the signal connection lines facing away from the substrate, and the first shielding structure at least partially overlaps with the first via transition region.

The first shielding structure includes a second shielding layer.

The display panel further includes a pixel defining layer, and the second shielding layer is located on a side of the pixel defining layer facing away from the substrate.

In a sixth aspect, the embodiments of the present application further provide a display device. The display device includes a display panel.

The display panel includes a display region and a non-display region, and the non-display region is located on at least one side of the display region.

The non-display region includes a bending region and a first via transition region, and the first via transition region is located on a side of the bending region facing the display region.

The display panel further includes a substrate and a signal routing located on a side of the substrate. The signal routing includes signal transmission lines and signal connection lines arranged in different layers, and the signal connection lines are located on a side of the signal transmission lines facing away from the substrate. The signal transmission lines and the signal connection lines are electrically connected through at least one connection via in the first via transition region.

The display panel further includes a silicon-nitride-based inorganic layer located on a side of the signal connection lines facing away from the substrate. The silicon-nitride-based inorganic layer is staggered from the first via transition region in the thickness direction of the display panel.

### BRIEF DESCRIPTION OF DRAWINGS

FIG. 1 illustrates a structure diagram of a display panel according to an embodiment of the present application.

FIG. 2 illustrates a section view taken along the direction C-C′ of the display panel illustrated in FIG. 1.

FIG. 3 illustrates another section view taken along the direction C-C′ of the display panel illustrated in FIG. 1.

FIG. 4 illustrates a section view taken along the direction D-D′ of the display panel illustrated in FIG. 1.

FIG. 5 illustrates yet another section view taken along the direction C-C′ of the display panel illustrated in FIG. 1.

FIG. 6 illustrates another section view taken along the direction D-D′ of the display panel illustrated in FIG. 1.

FIG. 7 illustrates a partial schematic diagram of a non-display region according to an embodiment of the present application.

FIG. 8 illustrates a section view taken along the direction E-E′ of the non-display region illustrated in FIG. 7.

FIG. 9 illustrates a section view taken along the direction F-F′ of the non-display region illustrated in FIG. 7.

FIG. 10 illustrates another partial schematic diagram of a non-display region according to an embodiment of the present application.

FIG. 11 illustrates yet another partial schematic diagram of a non-display region according to an embodiment of the present application.

FIG. 12 illustrates a section view taken along the direction M-M′ of the non-display region illustrated in FIG. 11.

FIG. 13 illustrates a section view taken along the direction N-N′ of the non-display region illustrated in FIG. 11.

FIG. 14 illustrates yet another partial schematic diagram of a non-display region according to an embodiment of the present application.

FIG. 15 illustrates yet another partial schematic diagram of a non-display region according to an embodiment of the present application.

FIG. 16 illustrates another structure diagram of a display panel according to an embodiment of the present application.

FIG. 17 illustrates another section view taken along the direction F-F′ of the non-display region illustrated in FIG. 7.

FIG. 18 illustrates yet another section view taken along the direction C-C′ of the display panel illustrated in FIG. 1.

FIG. 19 illustrates yet another section view taken along the direction D-D′ of the display panel illustrated in FIG. 1.

FIG. 20 illustrates a section view taken along the direction G-G′ of the display panel illustrated in FIG. 1.

FIG. 21 illustrates another section view taken along the direction G-G′ of the display panel illustrated in FIG. 1.

FIG. 22 illustrates yet another section view taken along the direction G-G′ of the display panel illustrated in FIG. 1.

FIG. 23 illustrates yet another section view taken along the direction G-G′ of the display panel illustrated in FIG. 1.

FIG. 24 illustrates another section view taken along the direction E-E′ of the non-display region illustrated in FIG. 7.

FIG. 25 illustrates yet another section view taken along the direction F-F′ of the non-display region illustrated in FIG. 7.

FIG. 26 illustrates another section view taken along the direction M-M′ of the non-display region illustrated in FIG. 11.

FIG. 27 illustrates another section view taken along the direction N-N′ of the non-display region illustrated in FIG. 11.

FIG. 28 illustrates yet another section view taken along the direction F-F′ of the non-display region illustrated in FIG. 7.

FIG. 29 illustrates a structure diagram of a display device according to an embodiment of the present application.

### DETAILED DESCRIPTION

To make the objects, technical solutions, and advantages of the present application clearer, the technical solutions of the present application are completely described below through embodiments and in conjunction with the drawings in the embodiments of the present application. Apparently, the described embodiments are part, not all, of the embodiments of the present application, and based on the embodiments of the present application, all other embodiments obtained by those of ordinary skill in the art are within the scope of the present application on the premise that no creative work is done.

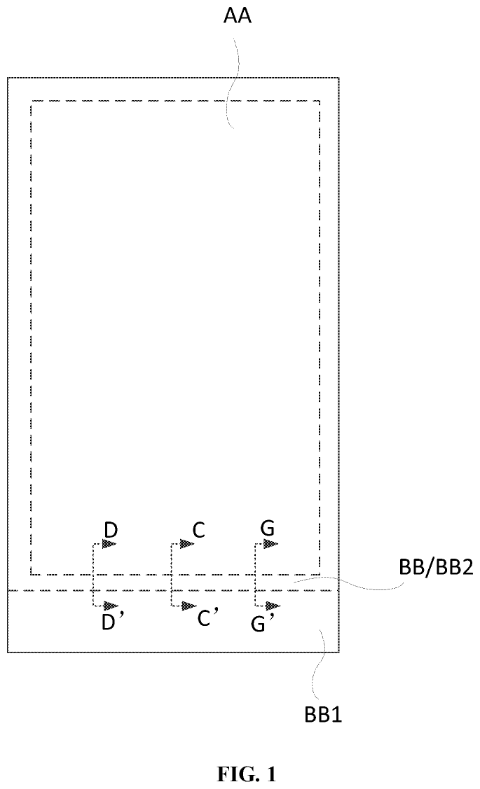

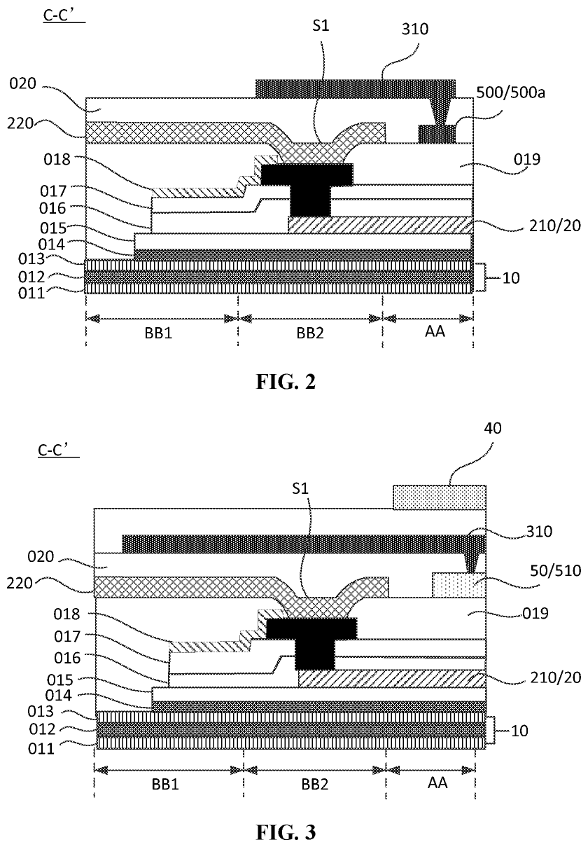

FIG. 1 illustrates a structure diagram of a display panel according to an embodiment of the present application, and FIG. 2 illustrates a section view taken along the direction C-C′ of the display panel illustrated in FIG. 1. Referring to FIGS. 1 and 2, the display panel includes a display region AA and a non-display region BB, and the non-display region BB is located on at least one side of the display region AA. The non-display region BB includes a bending region BB1 and a first via transition region BB2, and the first via transition region BB2 is located on a side of the bending region BB1 facing the display region AA. The display panel further includes a substrate 10 and a signal routing 20 located on a side of the substrate 10. The signal routing 20 includes signal transmission lines 210 and signal connection lines 220 arranged in different layers, and the signal connection lines 220 are located on a side of the signal transmission lines 210 facing away from the substrate 10. The signal transmission lines 210 and the signal connection lines 220 are electrically connected through at least one connection via S1 in the first via transition region BB2. The display panel further includes a first shielding structure 310. The first shielding structure 310 is located on a side of the signal connection lines 220 facing away from the substrate 10, and in the thickness direction of the display panel, the first shielding structure 310 at least partially overlaps with the first via transition region BB2.

In an example, as shown in FIG. 1, the display panel includes a display region AA and a non-display region BB. The display region AA may include multiple light-emitting elements (not shown) and a pixel circuit (not shown). The pixel circuit is electrically connected to the light-emitting elements, and various drive signals are provided for the light-emitting elements through the pixel circuit to drive the light-emitting elements to emit light, thereby achieving the image display in the display region AA. The non-display region BB surrounds at least a part of the display region AA. In an example, the non-display region BB may be the bezel region of the display panel. For example, the non-display region BB may include an upper bezel region, a lower bezel region, a left bezel region, and a right bezel region. The left bezel region and/or the right bezel region may be provided with a gate driver circuit (not shown). The gate driver circuit may include a shift register including multiple cascaded shift register circuits. An output terminal of each shift register circuit is electrically connected to the light-emitting elements of the same row through a scan signal line, and then a scan signal is provided for the light-emitting elements through the gate driver circuit. The lower bezel region may include a bending region BB1 and a first via transition region BB2. The first via transition region BB2 is located on a side of the bending region BB1 facing the display region AA, that is, the first via transition region BB2 is located between the bending region BB1 and the display region AA. It should be understood that the first via transition region BB2 may be the junction between the bending region BB1 and the display region AA.

In an example, in the implementation shown in FIG. 2, the display panel further includes a substrate 10 and a signal routing 20 located on a side of the substrate 10. The substrate 10 may include a stacked structure composed of a first flexible base layer 011, a first buffer layer 012, and a second flexible base layer 013. The materials of the first flexible base layer 011 and the second flexible base layer 013 may include polyimide (PI). PI has excellent flexibility, bending resistance, and certain high temperature resistance and thus provides a physical basis for bending and curling of subsequent processes and final products. The signal routing 20 may be a data signal routing connected to the pixel circuit in the display region AA and may also serve as a signal routing in the left bezel region and/or the right bezel region, such as a gate signal routing connected to the gate driver circuit. The present application is not limited thereto, and those skilled in the art may make corresponding configurations of the signal routing 20 according to actual requirements. One end of the data signal routing is electrically connected to the pixel circuit in the display region AA, and the other end of the data signal routing is electrically connected to a driver chip (not shown) located in the bending region BB1. Similarly, one end of the gate signal routing is electrically connected to the gate driver circuit in the left bezel region and/or the right bezel region, and the other end is electrically connected to the driver chip located in the bending region BB1, so that various drive signals may be provided through the driver chip. As can be seen from the above, the signal routing 20 extends from the display region AA or the left and right bezel regions to the driver chip in the bending region BB1 and is bent in the bending region BB1 to a non-light-emitting side of the display panel. Furthermore, by arranging the signal routing 20 to undergo layer switching at the junction between the bending region BB1 and the display region AA, that is, in the first via transition region BB2, the signal routing 20 includes signal transmission lines 210 and signal connection lines 220 arranged in different layers, and The signal transmission lines 210 and the signal connection lines 220 are electrically connected through at least one connection via S1 in the first via transition region BB2. Thus, the bending stress experienced by the bending region BB1 when bent is dispersed through the at least one connection via S1.

In the related art, under the FIAA architecture, the overall width of the bending region is reduced, which results in an increased routing density of signal lines in the bending region. Consequently, the spacing between adjacent signal lines is compressed, thereby intensifying the influence of the electric field. Furthermore, during the preparation of a silicon-nitride-based inorganic layer above the signal routing, ammonia gas is introduced, and the introduced ammonia gas reacts with moisture to generate hydroxide ions. Meanwhile, at an edge of the display region adjacent to the first via transition region, an iodine-based polarizer layer may precipitate elemental iodine. The elemental iodine reacts with hydroxide ions to form iodide ions. Under the effect of the intensified electric field, and due to the first via transition region being located closest to the boundary of the display region, the iodide ions tend to accumulate on one or more connection vias in the first via transition region, and the accumulated iodide ions are prone to reacting with and corroding the one or more connection vias.

Therefore, in the embodiments of the present application, a first shielding structure 310 is provided on a side of the signal routing 20 facing away from the substrate 10. In one or more embodiments, the signal routing 20 includes signal transmission lines 210 and signal connection lines 220. The signal transmission lines 210 may be the portion of the signal routing 20 connected to the display region AA (or the portion connected to the left bezel region and/or the right bezel region), and the signal connection lines 220 may be the portion of the signal routing 20 connected to the bending region BB1. The signal transmission lines 210 and the signal connection lines 220 are electrically connected through at least one connection via S1 in the first via transition region BB2. By providing the first shielding structure 310 above the at least one connection via S1, that is, locating the first shielding structure 310 on a side of the signal connection lines 220 facing away from the substrate 10, and arranging the first shielding structure 310 to at least partially overlap with the first via transition region BB2 in the thickness direction of the display panel, the first shielding structure 310 physically blocks reactive ions from reaching the connection via S1, and the reactive ions are prevented from reacting with and corroding the material of the at least one connection via S1 in the first via transition region BB2, which otherwise leads to poor connection stability between the signal connection lines 220 and the signal transmission lines 210 and results in display abnormalities, thereby alleviating the corrosion in the first via transition region BB2 and improving the display performance of the display panel.

It should be noted that, to better illustrate the technical problem addressed by the present application, the foregoing solution is described by way of example with reactive ions being iodide ions, but the present application is not limited thereto. In other embodiments, the first shielding structure 310 may also be arranged to block other reactive ions that are liable to react with the material of the one or more connection vias S1. Those skilled in the art may make corresponding configurations of the first shielding structure 310 according to actual requirements.

It should be further noted that, in FIG. 1, the first via transition region BB2 and the bending region BB1 being located in the same plane are illustrated as an example to show their positional relationship. However, those skilled in the art will readily appreciate that, in actual products, at least a portion of the bending region BB1 is bent toward a non-light-emitting side of the display panel.

In summary, in the embodiments of the present application, a first shielding structure is provided on a side of signal connection lines facing away from a substrate, and the first shielding structure at least partially overlaps with a first via transition region in a thickness direction of a display panel. Accordingly, the first shielding structure blocks reactive ions generated by chemical reactions in film layers of the display panel other than a film layer in which the first shielding structure is located from entering the first via transition region. As such, the reactive ions are prevented from reacting with a material of the connection vias in the first via transition region and corroding the connection vias, thereby alleviating corrosion in the first via transition region and improving display performance of the display panel.

In one or more embodiments, on the basis of the preceding embodiments, still referring to FIG. 2, the first shielding structure 310 is electrically connected to a potential signal line 500. In one or more embodiments, the first shielding structure 310 may be a conductive structure. By electrically connecting the first shielding structure 310 to the potential signal line 500, the potential signal line 500 provides a fixed potential signal or a jumping potential signal for the first shielding structure 310. Thus, in addition to the physical blocking effect of the first shielding structure 310 against reactive ions, a potential signal is applied to the first shielding structure 310. The charged first shielding structure 310 can attract or repel the reactive ions to further block the reactive ions from reaching the connection via S1, thereby further alleviating the corrosion in the first via transition region BB2 and improving the display performance of the display panel.

On the basis of the preceding embodiments, the potential signal line 500 may include a fixed potential signal line 500a. In this case, the first shielding structure 310 is electrically connected to a fixed potential signal line 500a. In one or more embodiments, the signal transmitted in the fixed potential signal line 500a is a fixed potential signal. By electrically connecting the first shielding structure 310 to the fixed potential signal line 500a, the potential signal on the first shielding structure 310 becomes a fixed potential signal. Thus, the force exerted by the first shielding structure 310 on the reactive ions is consistently either repulsive or attractive. For example, when the reactive ions are negatively charged, the fixed potential signal on the first shielding structure 310 may be set to a positive fixed potential signal to attract the reactive ions to the first shielding structure 310, thereby reducing the number of reactive ions reaching the connection via S1 and alleviating the corrosion in the first via transition region BB2. Conversely, when the reactive ions are positively charged, the fixed potential signal on the first shielding structure 310 may be set to a negative fixed potential signal. Since the reactive ions typically enter from a side of the signal routing 20 facing away from the substrate 10, the repulsive force exerted by the first shielding structure 310 located on the signal routing 20 against the reactive ions can reduce the number of reactive ions that ultimately reach the at least one connection via S1, thereby alleviating the corrosion in the first via transition region BB2. Similarly, when the reactive ions are negatively charged, the fixed potential signal on the first shielding structure 310 may also be set to a positive potential signal. When the reactive ions are positively charged, the fixed potential signal on the first shielding structure 310 may also be set to a negative potential signal. Thus, by electrically connecting the first shielding structure 310 to the fixed potential signal line 500a, a continuous repulsive or attractive force can be applied to the reactive ions, thereby further reducing the number of reactive ions reaching the connection via S1 and alleviating the corrosion in the first via transition region BB2.

In one or more embodiments, on the basis of the preceding embodiments, FIG. 3 illustrates another section view taken along the direction C-C′ of the display panel illustrated in FIG. 1. Referring to FIG. 3, the display panel further includes an iodine-based polarizer layer 40 located on a side of the first shielding structure 310 facing away from the substrate 10. The display panel further includes a power supply routing 50 located on a side of the substrate 10. The power supply routing 50 includes a first power supply routing 510. The first shielding structure 310 is electrically connected to the first power supply routing 510. The first power supply routing 510 is arranged to provide a negative fixed potential signal for the first shielding structure 310.

In one or more embodiments, in the implementation shown in FIG. 3, the display panel further includes an iodine-based polarizer layer 40. The iodine-based polarizer layer 40 at least partially overlaps with the display region AA in the thickness direction of the display panel, thereby improving the light output effect of the display region AA through the iodine-based polarizer layer 40. Moreover, the iodine-based polarizer layer 40 is located on a side of the first shielding structure 310 facing away from the signal routing 20, that is, the first shielding structure 310 is located between the iodine-based polarizer layer 40 and the at least one connection via S1. Thus, when the iodine-based polarizer layer 40 precipitates elemental iodine under certain conditions and ammonia gas introduced during the preparation of the silicon-nitride-based inorganic layer reacts with water vapor to generate hydroxide ions under certain conditions, the iodide ions generated from the reaction between the elemental iodine and hydroxide ions are blocked by the first shielding structure 310, thereby reducing the number of iodide ions reaching the connection via S1 and alleviating the corrosion in the first via transition region BB2. Furthermore, the display panel further includes a power supply routing 50 located on a side of the substrate 10. The power supply routing 50 includes a first power supply routing 510. The first power supply routing 510 is arranged to provide a negative fixed potential signal. In an example, as shown in FIG. 3, the first power supply routing 510 may be disposed in the same layer as the signal connection lines 220. By electrically connecting the first shielding structure 310 to the first power supply routing 510, the first power supply routing 510 provides a negative fixed potential signal for the first shielding structure 310. Since iodide ions are themselves negatively charged, the first shielding structure 310 exerts a repulsive force on the iodide ions, thereby further reducing the number of reactive ions that ultimately reach the at least one connection via S1 and alleviating the corrosion in the first via transition region BB2.

It should be noted that the implementation shown in FIG. 3 describes the first power supply routing 510 being disposed in the same film layer as the signal connection lines 220 as an example, but the present application is not limited thereto. In other embodiments, the first power supply routing 510 may also be disposed in a film layer other than the film layer where the signal connection lines 220 are located.

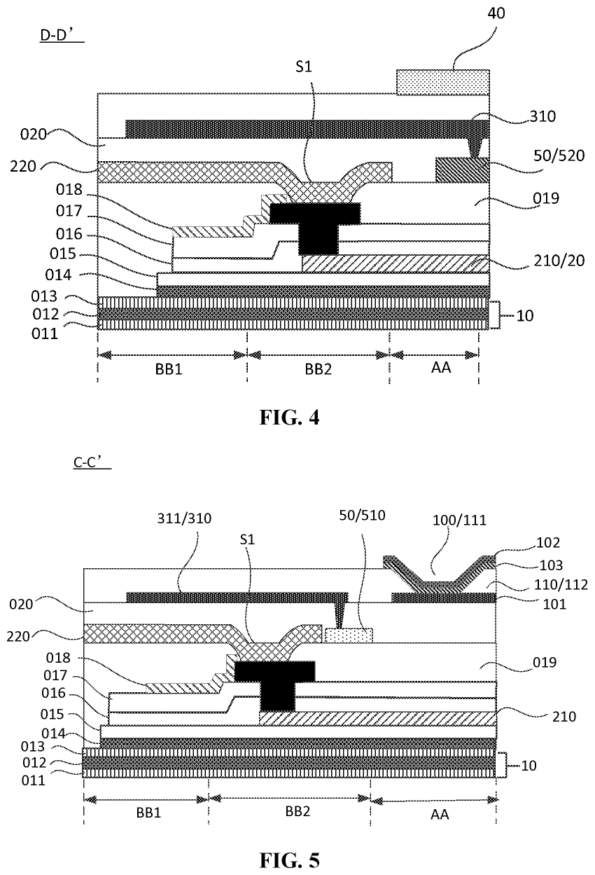

In one or more embodiments, in another embodiment, FIG. 4 illustrates a section view taken along the direction D-D′ of the display panel illustrated in FIG. 1. Referring to FIG. 4, the display panel further includes an iodine-based polarizer layer 40 located on a side of the first shielding structure 310 facing away from the substrate 10. The display panel further includes a power supply routing 50 located on a side of the substrate 10. The power supply routing 50 includes a second power supply routing 520. The first shielding structure 310 is electrically connected to the second power supply routing 520. The second power supply routing 520 is arranged to provide a positive fixed potential signal for the first shielding structure 310.

In one or more embodiments, as shown in FIG. 4, the display panel further includes an iodine-based polarizer layer 40. The iodine-based polarizer layer 40 at least partially overlaps with the display region AA in the thickness direction of the display panel, thereby improving the light output effect of the display region AA through the iodine-based polarizer layer 40. Moreover, the iodine-based polarizer layer 40 is located on a side of the first shielding structure 310 facing away from the signal routing 20, that is, the first shielding structure 310 is located between the iodine-based polarizer layer 40 and the at least one connection via S1. Thus, when the iodine-based polarizer layer 40 precipitates elemental iodine under certain conditions and ammonia gas introduced during the preparation of the silicon-nitride-based inorganic layer reacts with water vapor to generate hydroxide ions under certain conditions, the iodide ions generated from the reaction between the elemental iodine and hydroxide ions are blocked by the first shielding structure 310, thereby reducing the number of iodide ions reaching the connection via S1 and alleviating the corrosion in the first via transition region BB2. Furthermore, the display panel further includes a power supply routing 50 located on a side of the substrate 10. The power supply routing 50 includes a second power supply routing 520. The second power supply routing 520 is arranged to provide a positive fixed potential signal. In an example, as shown in FIG. 4, the second power supply routing 520 may be disposed in the same layer as the signal connection lines 220. By electrically connecting the first shielding structure 310 to the second power supply routing 520, the second power supply routing 520 provides a positive fixed potential signal for the first shielding structure 310. Since iodide ions are themselves negatively charged, the first shielding structure 310 exerts an attractive force on the iodide ions, thereby reducing the number of reactive ions that ultimately reach the at least one connection via S1 and alleviating the corrosion in the first via transition region BB2.

It should be noted that the implementation shown in FIG. 4 describes the second power supply routing 520 being disposed in the same film layer as the signal connection lines 220 as an example, but the present application is not limited thereto. In other embodiments, the second power supply routing 520 may also be disposed in a film layer other than the film layer where the signal connection lines 220 are located.

In one or more embodiments, in another embodiment, FIG. 5 illustrates yet another section view taken along the direction C-C′ of the display panel illustrated in FIG. 1. Referring to FIG. 5, the first shielding structure 310 includes a first shielding layer 311. The display panel further includes a pixel defining layer 110, and the first shielding layer 311 is located between the film layer where the signal connection lines 220 are located and the film layer where the pixel defining layer 110 is located.

In an example, in the implementation shown in FIG. 5, the display panel further includes a pixel defining layer 110. The portion of the pixel defining layer 110 located in the display region AA includes a pixel opening section 111 and a pixel defining section 112. The pixel defining section 112 is arranged surrounding the pixel opening section 111. Furthermore, the pixel defining layer 110 is located on a side of the signal connection lines 220 facing away from the substrate 10, and at least one planarization layer is interposed between the pixel defining layer 110 and the signal connection lines 220. By providing the first shielding layer 311 between the film layer where the signal connection lines 220 are located and the film layer where the pixel defining layer 110 is located, the distance between the first shielding layer 311 and the at least one connection via S1 in the thickness direction of the display panel is reduced, thereby further enhancing the physical blocking effect of the first shielding layer 311 against reactive ions and further alleviating the corrosion in the first via transition region BB2.

In one or more embodiments, on the basis of the preceding embodiments, still referring to FIG. 5, the display panel further includes a light-emitting element 100. The light-emitting element 100 includes a first electrode 101. The opening in the pixel defining layer 110 is arranged to expose at least a portion of the first electrode 101. The first electrode 101 is located in the display region AA, and the film layer where the first electrode 101 is located is located between the film layer where the signal connection lines 220 are located and the film layer where the pixel defining layer 110 is located. The first shielding structure 310 is disposed in the same layer as the first electrode 101 and is insulated from the first electrode 101.

In one or more embodiments, a light-emitting element 100 is disposed within the pixel opening section 111 in the display region AA. The light-emitting element 100 includes a first electrode 101, a second electrode 102, and a common light-emitting layer 103. The common light-emitting layer 103 is located within the pixel opening section 111. The second electrode 102 may serve as the cathode of the light-emitting element 100, and the first electrode 101 may serve as the anode of the light-emitting element 100. The common light-emitting layer 103 is located between the first electrode 101 and the second electrode 102. The first electrode 101 is electrically connected to the pixel circuit. The common light-emitting layer 103 may include multiple layers, such as a hole injection layer, a hole transport layer, a light-emitting layer, an electron transport layer, and an electron injection layer, that are arranged in a stacked manner. When no voltage is applied across the first electrode 101 and the second electrode 102, the light-emitting element 100 does not emit light. When a voltage is applied across the first electrode 101 and the second electrode 102, the first electrode injects holes into the hole injection layer, and the second electrode injects electrons into the electron injection layer. The holes and the electrons recombine in the light-emitting layer to form excitons, thereby resulting in radiative light emission. On the basis of the above, since the film layer where the first electrode 101 is located is located between the film layer where the signal connection lines 220 are located and the film layer where the pixel defining layer 110 is located, the first shielding structure 310 may be provided in the same layer as the first electrode 101 and is insulated from the first electrode 101. Thus, the first shielding layer 311 may be provided closer to the at least one connection via S1 in the thickness direction of the display panel, thereby enhancing the physical blocking effect of the first shielding structure 310 against reactive ions and alleviating the corrosion in the first via transition region BB2. Moreover, since the first shielding structure 310 and the first electrode 101 are located in the same film layer, the first shielding structure 310 and the first electrode 101 can be fabricated in the same process step using a single mask during manufacturing, and the need for separate masks for the first shielding structure 310 and the first electrode 101 is eliminated, thereby reducing costs, decreasing the number of process steps, and improving production efficiency.

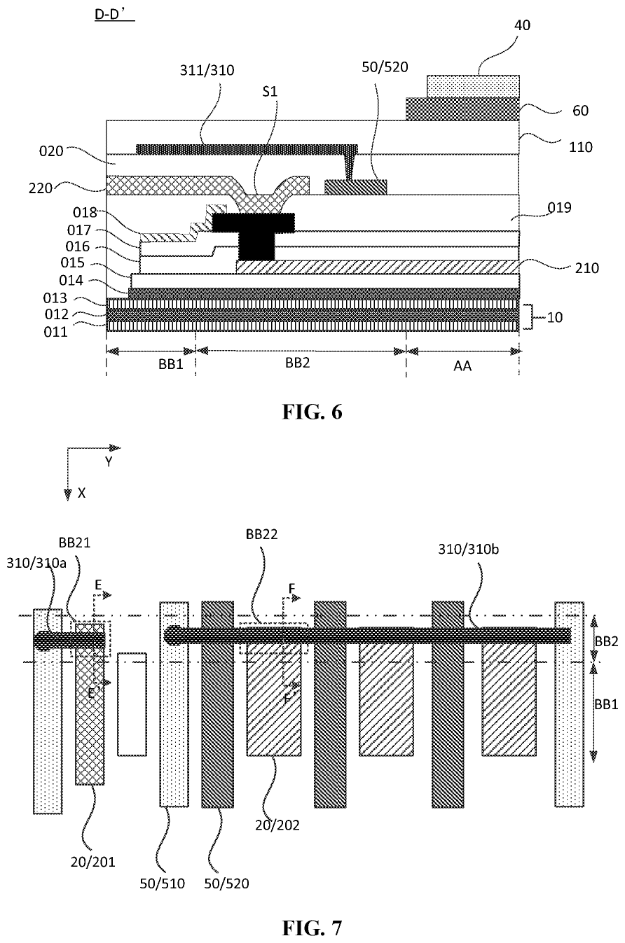

In one or more embodiments, on the basis of the preceding embodiments, FIG. 6 illustrates another section view taken along the direction D-D′ of the display panel illustrated in FIG. 1. Referring to FIG. 6, the display panel further includes a silicon-nitride-based inorganic layer 60 located on a side of the signal connection lines 220 facing away from the substrate 10. The silicon-nitride-based inorganic layer 60 is staggered from the first via transition region BB2 in the thickness direction of the display panel.

In one or more embodiments, the display panel further includes a silicon-nitride-based inorganic layer 60 located on a side of the signal connection lines 220 facing away from the substrate 10. In an example, in the implementation shown in FIG. 6, the silicon-nitride-based inorganic layer 60 is located on the surface of the pixel defining layer 110 facing away from the substrate 10. The light-emitting element within the pixel defining layer 110 is prevented from moisture and oxygen erosion through the silicon-nitride-based inorganic layer 60, thereby protecting the light-emitting element. It should be noted that the inorganic layer includes a silicon-nitride-based inorganic layer and a silicon-oxide-based inorganic layer, and the dielectric constant of the silicon-nitride-based inorganic layer is higher than the dielectric constant of the silicon-oxide-based inorganic layer. Typically, a silicon-nitride-based inorganic layer with a higher dielectric constant is prepared on the pixel defining layer 110. On one hand, the silicon-nitride-based inorganic layer has a denser structure and superior blocking properties compared to the silicon-oxide-based inorganic layer and thus can effectively block moisture and oxygen from the air. On the other hand, the silicon-nitride-based inorganic layer having a higher dielectric constant can provide better performance during the subsequent fabrication of other components. However, ammonia gas is introduced during the preparation of the silicon-nitride-based inorganic layer 60, and under certain conditions, the ammonia gas reacts with water vapor to generate hydroxide ions. Meanwhile, the iodine-based polarizer layer 40 located on a side of the silicon-nitride-based inorganic layer 60 facing away from the substrate 10 precipitates elemental iodine under certain conditions, and iodide ions generated from the reaction between the elemental iodine and hydroxide ions may corrode the at least one connection via S1. Therefore, in the embodiments of the present application, the silicon-nitride-based inorganic layer 60 is arranged to avoid the first via transition region BB2, that is, the silicon-nitride-based inorganic layer 60 is staggered from the first via transition region BB2 in the thickness direction of the display panel. Since the silicon-nitride-based inorganic layer 60 is not prepared in the first via transition region BB2, the amount of ammonia gas introduced in the first via transition region BB2 is reduced, thereby decreasing the number of generated hydroxide ions. Thus, although the iodine-based polarizer layer 40 may still release elemental iodine under certain conditions, the decreased number of hydroxide ions leads to a corresponding reduction in the number of iodide ions ultimately generated from the reaction. From another perspective, consequently, the number of iodide ions reaching the connection via S1 is reduced, thereby further alleviating the corrosion in the first via transition region BB2.

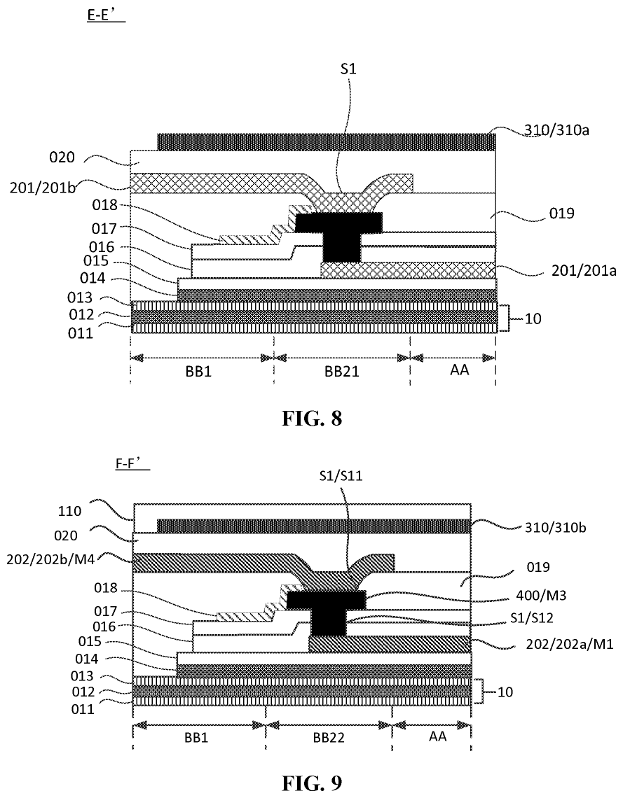

In one or more embodiments, on the basis of the preceding embodiments, FIG. 7 illustrates a partial schematic diagram of a non-display region according to an embodiment of the present application, FIG. 8 illustrates a section view taken along the direction E-E′ of the non-display region illustrated in FIG. 7, and FIG. 9 illustrates a section view taken along the direction F-F′ of the non-display region illustrated in FIG. 7. Referring to FIGS. 7 to 9, the signal routing 20 includes a gate signal routing 201 and a data signal routing 202. The first via transition region BB2 includes a gate line via transition region BB21 and a data line via transition region BB22. The gate signal routing 201 includes gate signal transmission lines 201a and gate signal connection lines 201b arranged in different layers. The gate signal connection lines 201b are located on a side of the gate signal transmission lines 201a facing away from the substrate 10, and the gate signal transmission lines 201a and the gate signal connection lines 201b are electrically connected through at least one connection via S1 in the gate line via transition region BB21. The data signal routing 202 includes data signal transmission lines 202a and data signal connection lines 202b arranged in different layers. The data signal connection lines 202b are located on a side of the data signal transmission lines 202a facing away from the substrate 10, and the data signal transmission lines 202a and the data signal connection lines 202b are electrically connected through at least one connection via S1 in the data line via transition region BB22. The first shielding structure 310 includes a gate shielding structure section 310a and a data shielding structure section 310b. In the thickness direction of the display panel, the gate shielding structure section 310a at least partially overlaps with the gate line via transition region BB21, and the data shielding structure section 310b at least partially overlaps with the data line via transition region BB22.

In one or more embodiments, as shown in FIG. 7, the lower bezel region of the display panel includes multiple signal routings 20 and multiple power supply routings 50. The signal routing 20 may include a gate signal routing 201 and a data signal routing 202. The power supply routing 50 may include a first power supply routing 510 and a second power supply routing 520. The first power supply routing 510 may transmit a negative fixed potential signal, and the second power supply routing 520 may transmit a positive fixed potential signal. Assuming the direction from the first via transition region BB2 toward the bending region BB1 is defined as a first direction X and a second direction Y intersects the first direction X, the power supply routings 50 and the signal routings 20 extend in the first direction X and are arranged in the second direction Y. Since one end of the gate signal routing 201 is electrically connected to the gate driver circuit in the left bezel region and/or the right bezel region, the gate signal routing 201 is located at the edge of the lower bezel region in the second direction Y to facilitate the electrical connection to the gate driver circuit. The first power supply routing 510 is arranged surrounding at least a portion of the display region AA. Therefore, by arranging the first power supply routing 510 at the edge of the lower bezel region in the second direction Y, the routing of the first power supply routing 510 is made more convenient. One end of the data signal routing 202 is electrically connected to the pixel circuit in the display region AA, and thus, all the data signal routings 202 can be concentrated in the central region of the lower bezel region for routing.

On the basis of the above, referring to FIGS. 7 and 8, the first via transition region BB2 includes a gate line via transition region BB21. The gate line via transition region BB21 is located on a side of the bending region BB1 facing the display region AA. The gate signal routing 201 includes gate signal transmission lines 201a and gate signal connection lines 201b arranged in different layers. The gate signal connection lines 201b are located on a side of the gate signal transmission lines 201a facing away from the substrate 10. The gate signal connection lines 201b may be electrically connected to the driver chip located in the bending region BB1, and the gate signal transmission lines 201a may be electrically connected to the gate driver circuit located in the left bezel region and/or the right bezel region. The gate signal transmission lines 201a and the gate signal connection lines 201b are electrically connected through at least one connection via S1 in the gate line via transition region BB21 to disperse the bending stress experienced by the bending region BB1 when bent. The first shielding structure 310 includes a gate shielding structure section 310a, and the gate shielding structure section 310a at least partially overlaps with the gate line via transition region BB21 in the thickness direction of the display panel. Thus, the gate shielding structure section 310a blocks reactive ions from reaching the connection via S1 in the gate line via transition region BB21, and the reactive ions are prevented from reacting with the material of the connection via S1 in the gate line via transition region BB21 and corroding the connection via S1, thereby alleviating the corrosion phenomenon in the gate line via transition region BB21 and improving the display performance of the display panel.

On the basis of the above, referring to FIGS. 7 and 9, the first via transition region BB2 further includes a data line via transition region BB22. The data line via transition region BB22 is located on a side of the bending region BB1 facing the display region AA. The data signal routing 202 includes data signal transmission lines 202a and data signal connection lines 202b arranged in different layers. The data signal connection lines 202b are located on a side of the data signal transmission lines 202a facing away from the substrate 10. The data signal connection lines 202b may be electrically connected to the driver chip located in the bending region BB1, and the data signal transmission lines 202a may be electrically connected to the pixel circuit located in the display region AA. The data signal transmission lines 202a and the data signal connection lines 202b are electrically connected through at least one connection via S1 in the data line via transition region BB22 to disperse the bending stress experienced by the bending region BB1 when bent. The first shielding structure 310 includes a data shielding structure section 310b, and the data shielding structure section 310b at least partially overlaps with the data line via transition region BB22 in the thickness direction of the display panel. Thus, the data shielding structure section 310b blocks reactive ions from reaching the connection via S1 in the data line via transition region BB22, and the reactive ions are prevented from reacting with the material of the connection via S1 in the data line via transition region BB22 and corroding the connection via S1, thereby alleviating the corrosion phenomenon in the data line via transition region BB22 and improving the display performance of the display panel.

In one or more embodiments, on the basis of the preceding embodiments, still referring to FIG. 7, the gate shielding structure section 310a and the data shielding structure section 310b are connected to a same potential signal line.

In an example, in the implementation shown in FIG. 7, both the gate shielding structure section 310a and the data shielding structure section 310b are electrically connected to the first power supply routing 510 to provide a negative fixed potential signal for the gate shielding structure section 310a and the data shielding structure section 310b through the first power supply routing 510, respectively. Thus, the gate shielding structure section 310a and the data shielding structure section 310b exert either repulsive or attractive forces on the reactive ions, thereby further reducing the number of reactive ions reaching the connection via S1 and alleviating the corrosion in the first via transition region BB2. It should be noted that FIG. 7 merely illustrates an example where both the gate shielding structure section 310a and the data shielding structure section 310b are electrically connected to the first power supply routing 510, but the present application is not limited thereto. In other embodiments, the gate shielding structure section 310a and the data shielding structure section 310b may also be electrically connected to the second power supply routing 520 to provide a positive fixed potential signal for the gate shielding structure section 310a and the data shielding structure section 310b through the second power supply routing 520, respectively.

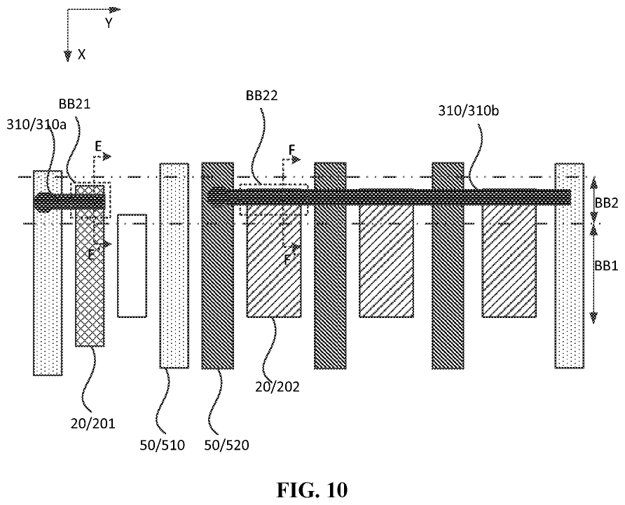

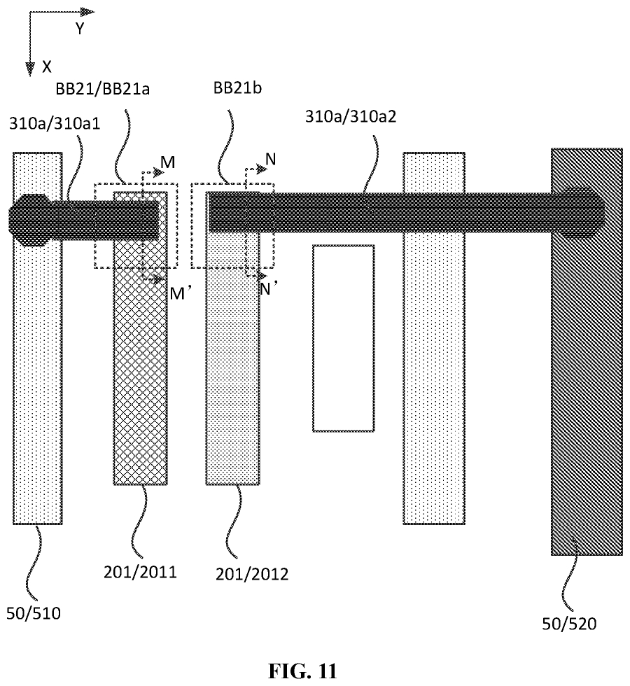

In one or more embodiments, in another embodiment, FIG. 10 illustrates another partial schematic diagram of a non-display region according to an embodiment of the present application. Referring to FIG. 10, the gate shielding structure section 310a and the data shielding structure section 310b are independently provided, and the gate shielding structure section 310a and the data shielding structure section 310b are connected to different potential signal lines.

In one or more embodiments, in the implementation shown in FIG. 10, the gate shielding structure section 310a and the data shielding structure section 310b are independently provided. The gate shielding structure section 310a is electrically connected to the first power supply routing 510 to provide a negative fixed potential signal for the gate shielding structure section 310a through the first power supply routing 510. The data shielding structure section 310b is electrically connected to the second power supply routing 520 to provide a positive fixed potential signal for the data shielding structure section 310b through the second power supply routing 520. It should be understood that, in other embodiments, the gate shielding structure section 310a may also be set to be electrically connected to the second power supply routing 520, and the data shielding structure section 310b may also be set to be electrically connected to the first power supply routing 510. The present application is not limited thereto, and those skilled in the art may make corresponding configurations of the above connection relationship according to actual requirements.

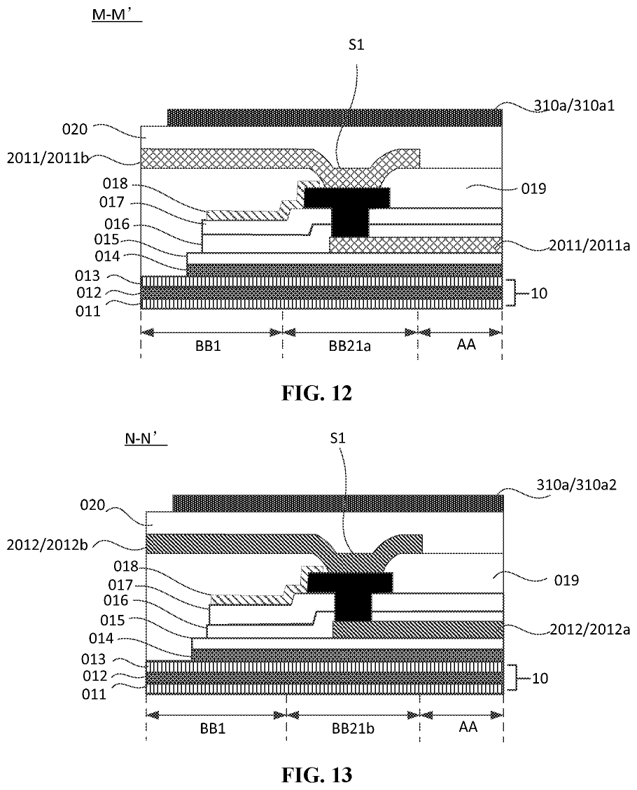

In one or more embodiments, FIG. 11 illustrates yet another partial schematic diagram of a non-display region according to an embodiment of the present application, FIG. 12 illustrates a section view taken along the direction M-M′ of the non-display region illustrated in FIG. 11, and FIG. 13 illustrates a section view taken along the direction N-N′ of the non-display region illustrated in FIG. 11. Referring to FIGS. 11 to 13, the gate signal routing 201 includes a first gate signal routing 2011 and a second gate signal routing 2012, and a level of signals transmitted through the first gate signal routing 2011 is opposite to a level of signals transmitted through the second gate signal routing 2012. The gate line via transition region BB21 includes a first via transition sub-region BB21a and a second via transition sub-region BB21b. The first gate signal routing 2011 includes first gate signal transmission lines 2011a and first gate signal connection lines 2011b arranged in different layers. The first gate signal connection lines 2011b are located on a side of the first gate signal transmission lines 2011a facing away from the substrate 10. The first gate signal transmission lines 2011a and the first gate signal connection lines 2011b are electrically connected through at least one connection via S1 in the first via transition sub-region BB21a. The second gate signal routing 2012 includes second gate signal transmission lines 2012a and second gate signal connection lines 2012b arranged in different layers. The second gate signal connection lines 2012b are located on a side of the second gate signal transmission lines 2012a facing away from the substrate 10. The second gate signal transmission lines 2012a and the second gate signal connection lines 2012b are electrically connected through at least one connection via S1 in the second via transition sub-region BB21b. The gate shielding structure section 310a includes a first sub-shielding structure 310a1 and a second sub-shielding structure 310a2. In the thickness direction of the display panel, the first sub-shielding structure 310a1 at least partially overlaps with the first via transition sub-region BB21a, and the second sub-shielding structure 310a2 at least partially overlaps with the second via transition sub-region BB21b. A potential signal line connected to the first sub-shielding structure 310a1 is different from a potential signal line connected to the second sub-shielding structure 310a2.

In one or more embodiments, as shown in FIGS. 11 and 12, the gate signal routing 201 includes a first gate signal routing 2011 and a second gate signal routing 2012, and a level of signals transmitted through the first gate signal routing 2011 is opposite to a level of signals transmitted through the second gate signal routing 2012. For example, the first gate signal routing 2011 may transmit a fixed low-level signal, and the second gate signal routing 2012 may transmit a fixed high-level signal. The first gate signal routing 2011 includes first gate signal transmission lines 2011a and first gate signal connection lines 2011b arranged in different layers. The first gate signal connection lines 2011b are located on a side of the first gate signal transmission lines 2011a facing away from the substrate 10. The first gate signal connection lines 2011b may be electrically connected to the driver chip located in the bending region BB1, and the first gate signal transmission lines 2011a may be electrically connected to the gate driver circuit located in the left bezel region and/or the right bezel region to provide a fixed high-level signal for the gate driver circuit. The gate line via transition region BB21 includes a first via transition sub-region BB21a. The first gate signal transmission lines 2011a and the first gate signal connection lines 2011b are electrically connected through at least one connection via S1 in the first via transition sub-region BB21a. By arranging the first sub-shielding structure 310a1 to at least partially overlap with the first via transition sub-region BB21a in the thickness direction of the display panel, the first sub-shielding structure 310a1 blocks reactive ions from reaching the connection via S1 in the first via transition sub-region BB21a, thereby alleviating the corrosion phenomenon in the first via transition sub-region BB21a and improving the display performance of the display panel. Furthermore, the first sub-shielding structure 310a1 may be electrically connected to the first power supply routing 510 to provide a negative fixed potential signal for the first sub-shielding structure 310a1 through the first power supply routing 510, and the first sub-shielding structure 310a1 then exerts either repulsive or attractive forces on the reactive ions, thereby further reducing the number of reactive ions reaching the connection via S1 and alleviating the corrosion phenomenon in the first via transition sub-region BB21a.

Similarly, as shown in FIGS. 11 and 13, the second gate signal routing 2012 includes second gate signal transmission lines 2012a and second gate signal connection lines 2012b arranged in different layers. The second gate signal connection lines 2012b are located on a side of the second gate signal transmission lines 2012a facing away from the substrate 10. The second gate signal connection lines 2012b may be electrically connected to the driver chip located in the bending region BB1, and the second gate signal transmission lines 2012a may be electrically connected to the gate driver circuit located in the left bezel region and/or the right bezel region to provide a fixed low-level signal for the gate driver circuit. The gate line via transition region BB21 further includes a second via transition sub-region BB21b. The second gate signal transmission line 2012a and the second gate signal connection line 2012b are electrically connected through at least one connection via S1 in the second via transition sub-region BB21b. By arranging the second sub-shielding structure 310a2 to at least partially overlap with the second via transition sub-region BB21b in the thickness direction of the display panel, the second sub-shielding structure 310a2 blocks reactive ions from reaching the connection via S1 in the second via transition sub-region BB21b, thereby alleviating the corrosion phenomenon in the second via transition sub-region BB21b and improving the display performance of the display panel. Furthermore, the second sub-shielding structure 310a2 may be electrically connected to the second power supply routing 520 to provide a positive fixed potential signal for the second sub-shielding structure 310a2 through the second power supply routing 520, and the second sub-shielding structure 310a2 then exerts either repulsive or attractive forces on the reactive ions, thereby further reducing the number of reactive ions reaching the connection via S1 and alleviating the corrosion phenomenon in the first via transition sub-region BB21a.

It should be understood that since the signals transmitted by the first gate signal routing 2011 and the second gate signal routing 2012 are at opposite levels, different fixed potential signals may be provided for the first sub-shielding structure 310a1 arranged on the first gate signal routing 2011 and the second sub-shielding structure 310a2 arranged on the second gate signal routing 2012, respectively. In an example, in the implementation shown in FIG. 11, if the first gate signal routing 2011 transmits a fixed low-level signal, the first sub-shielding structure 310a1 is electrically connected to the first power supply routing 510 to provide a negative fixed potential signal for the first sub-shielding structure 310a1, thereby avoiding any influence of the first sub-shielding structure 310a1 on the signal transmitted by the first gate signal routing 2011. Similarly, if the second gate signal routing 2012 transmits a fixed high-level signal, the second sub-shielding structure 310a2 is electrically connected to the second power supply routing 520 to provide a positive fixed potential signal for the second sub-shielding structure 310a2, thereby avoiding any influence of the second sub-shielding structure 310a2 on the signal transmitted by the second gate signal routing 2012.

It should be understood that the embodiments of the present application do not impose limitations on the positions of the first via transition sub-region BB21a and the second via transition sub-region BB21b. Preferably, in the first direction X, the first via transition sub-region BB21a and the second via transition sub-region BB21b are arranged in a staggered manner, where the first direction X is a direction from the display region AA toward the bending region BB1.

In one or more embodiments, on the basis of the preceding embodiments, still referring to FIG. 7, the first via transition region BB2 includes multiple connection vias, and the multiple connection vias are arranged in the second direction Y. The first shielding structure 310 extends in the second direction Y, and the second direction Y intersects the direction from the display region AA toward the bending region BB1.

In one or more embodiments, as shown in FIG. 7, the gate signal routing 201 and the data signal routing 202 extend in the first direction X and are arranged in the second direction Y, where the first direction X is the direction from the display region AA toward the bending region BB1, and the second direction Y intersects the first direction X. The gate line via transition region BB21 and the data line via transition region BB22 are arranged in the second direction Y in the first via transition region BB2, causing multiple connection vias in the first via transition region BB2 to be arranged in the second direction Y. On the basis of the above, by arranging the first shielding structure 310 to extend in the second direction Y, the first shielding structure 310 can simultaneously overlap with multiple connection vias in the thickness direction of the display panel, thereby ensuring a simple configuration of the first shielding structure 310.

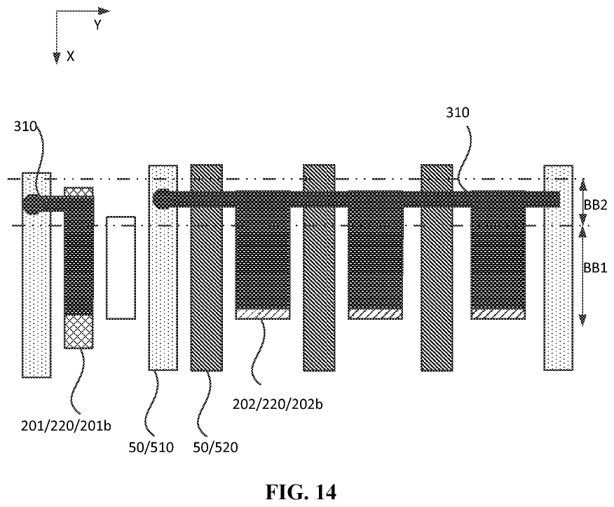

In yet another embodiment, FIG. 14 illustrates yet another partial schematic diagram of a non-display region according to an embodiment of the present application. Referring to FIG. 14, the first shielding structure 310 further at least partially overlaps with the signal connection lines 220. In one or more embodiments, in the implementation shown in FIG. 14, the signal routing 20 includes a gate signal routing 201 and a data signal routing 202. Accordingly, the signal connection lines 220 include gate signal connection lines 201b and data signal connection lines 202b. Both the gate signal connection lines 201b and the data signal connection lines 202b are electrically connected to the driver chip located in the bending region BB1. By arranging the first shielding structure 310 to at least partially overlap with both the gate signal connection lines 201b and the data signal connection lines 202b in a thickness direction of the display panel, the first shielding structure 310 is also capable of providing a blocking function in a region of the bending region BB1 adjacent to a first via transition region BB2. As such, reactive ions are prevented from bypassing the first shielding structure 310 at a junction region between the first via transition region BB2 and the bending region BB1, thereby further enhancing a blocking effect of the first shielding structure 310.

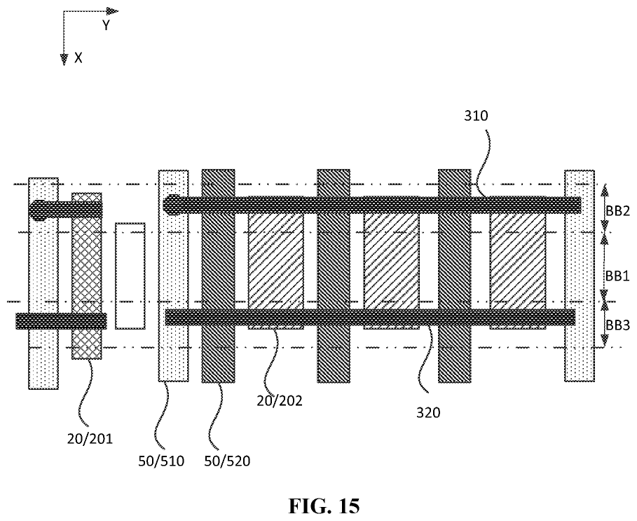

In one or more embodiments, FIG. 15 illustrates yet another partial schematic diagram of a non-display region according to an embodiment of the present application. Referring to FIG. 15, the display panel further includes a second via transition region BB3. The second via transition region BB3 is located on a side of the bending region BB1 facing away from the first via transition region BB2. The display panel further includes a second shielding structure 320. In the thickness direction of the display panel, the second shielding structure 320 at least partially overlaps with the second via transition region BB3.

In one or more embodiments, as shown in FIG. 15, the second via transition region BB3 is located on a side of the bending region BB1 facing away from the first via transition region BB2, that is, the bending region BB1 is located between the second via transition region BB3 and the first via transition region BB2. Since the first shielding structure 310 is arranged above the first via transition region BB2, to balance the bending stress experienced by the bending region BB1 when bent, a second shielding structure 320 is provided above the second via transition region BB3, that is, in the thickness direction of the display panel, the second shielding structure 320 at least partially overlaps with the second via transition region BB3. It should be understood that since the second via transition region BB3 is located on a side of the bending region BB1 facing away from the first via transition region BB2, that is, the second via transition region BB3 is farther from the boundary of the display region AA, the elemental iodine released by the iodine-based polarizer layer in the display region AA has greater difficulty reaching the second via transition region BB3. Therefore, the corrosion phenomenon at the location of the second via transition region BB3 is less severe than the corrosion phenomenon at the first via transition region BB2.

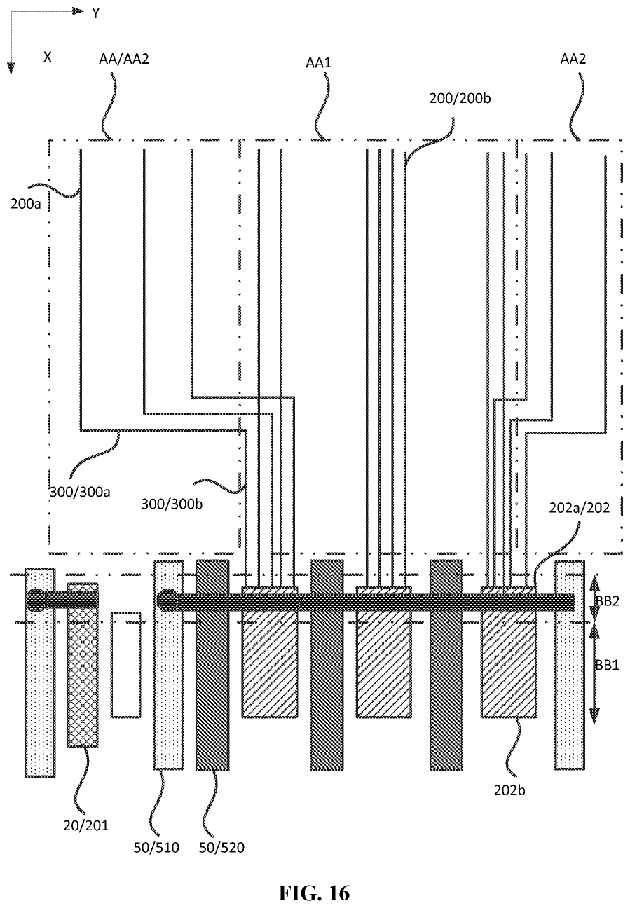

In one or more embodiments, on the basis of the preceding embodiments, FIG. 16 illustrates another structure diagram of a display panel according to an embodiment of the present application. Referring to FIG. 16, the display region AA further includes data signal lines 200 and a signal wiring 300. The data signal lines 200 include first data signal lines 200a and second data signal lines 200b. The display region AA includes a first display region AA1 and a second display region AA2. The second display region AA2 is located on both sides of the first display region AA1 in the second direction Y, where the second direction Y intersects the direction from the display region AA toward the bending region BB1. The first data signal lines 200a are located in the second display region AA2, and the second data signal lines 200b are located in the first display region AA1. The first data signal lines 200a are electrically connected to the data signal transmission lines 202a in the first via transition region BB2 through the signal wirings 300. The second data signal lines 200b are electrically connected to the data signal transmission lines 202a in the first via transition region BB2. The signal wirings 300 include a first signal wiring 300a and a second signal wiring 300b connected to each other. The extending direction of the first signal wiring 300a intersects the extending direction of the second signal wiring 300b.

In one or more embodiments, as shown in FIG. 16, the display region AA includes a first display region AA1 and a second display region AA2. The second display region AA2 is located on both sides of the first display region AA1 in the second direction Y. Compared to the first display region AA1, the second display region AA2 is closer to the boundary of the display region AA. Furthermore, the display region AA includes first data signal lines 200a and second data signal lines 200b. The first data signal lines 200a are located in the second display region AA2, that is, at the boundary of the display region AA. The first via transition region BB2 includes a data signal routing 202, and the data signal routing 202 includes data signal transmission lines 202a and data signal connection lines 202b. The data signal connection lines 202b are electrically connected to the driver chip in the bending region BB1, and the data signal transmission lines 202a are electrically connected to either the first data signal lines 200a or the second data signal lines 200b in the display region AA, so that the driver chip transmits a data signal to the first data signal lines 200a or the second data signal lines 200b in the display region AA. On the basis of the above, the first data signal lines 200a are electrically connected to the data signal transmission lines 202a in the first via transition region BB2 through the first signal wiring 300a and the second signal wiring 300b, whose extension directions intersect. The second data signal lines 200b are directly electrically connected to the data signal transmission lines 202a in the first via transition region BB2. Thus, the routing of all the data signal lines 200 is centralized in the central region of the display region AA, thereby facilitating the reduction of the width of the bending region BB1 in the second direction Y.

In one or more embodiments, on the basis of the preceding embodiments, still referring to FIG. 9, the display panel further includes a first metal layer M1, a third metal layer M3, and a fourth metal layer M4 that are arranged in a stacked manner on a side of the substrate 10. The signal routing 20 includes a data signal routing 202. The data signal routing 202 includes data signal transmission lines 202a and data signal connection lines 202b. The data signal transmission lines 202a are located in the first metal layer M1, and the data signal connection lines 202b are located in the fourth metal layer M4. The display panel further includes a first bridging structure 400. The first bridging structure 400 is located in the third metal layer M3. The connection vias S1 include a first connection via S11 and a second connection via S12. In the thickness direction of the display panel, a first connection via S11 at least partially overlaps with a second connection via S12 so that the first connection via S11 communicates with the second connection via S12 through the first bridging structure 400. The data signal connection lines 202b are electrically connected to the first bridging structure 400 through the first connection via S11, and the first bridging structure 400 is electrically connected to the data signal transmission lines 202a through the second connection via S12. Thus, the electrical connection between a data signal transmission lines 202a located in the first metal layer M1 and the data signal connection lines 202b located in the fourth metal layer M4 is achieved through the first bridging structure 400, the first connection via S11, and the second connection via S12, thereby ensuring a simple connection between the data signal transmission lines 202a and the data signal connection lines 202b.

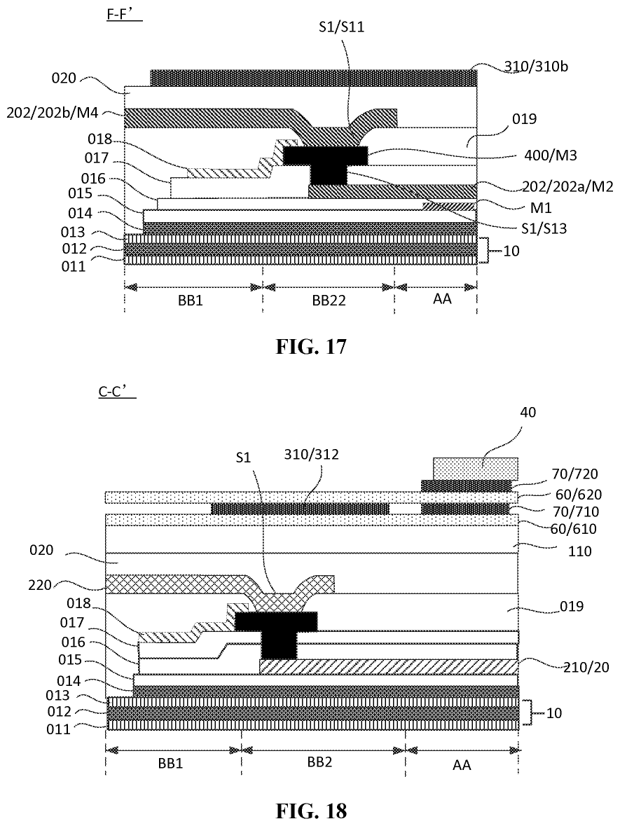

It should be understood that a second metal layer M2 may also be provided and is located between the first metal layer M1 and the third metal layer M3. Since the data signal transmission lines 202a are electrically connected to the data signal lines in the display region and the data signal lines are typically located in the first metal layer M1 or the second metal layer M2, the data signal transmission lines 202a in the first via transition region BB2 may be located in either the first metal layer M1 or the second metal layer M2. In other embodiments, FIG. 17 illustrates another section view taken along the direction F-F′ of the non-display region illustrated in FIG. 7. Referring to FIGS. 7 and 17, the display panel includes a first metal layer M1, a second metal layer M2, a third metal layer M3, and a fourth metal layer M4 that are arranged in a stacked manner on a side of the substrate 10. The signal routing 20 includes a data signal routing 202. The data signal routing 202 includes data signal transmission lines 202a and data signal connection lines 202b. The data signal transmission lines 202a are located in the second metal layer M2, and the data signal connection lines 202b are located in the fourth metal layer M4. The display panel further includes a first bridging structure 400. The first bridging structure 400 is located in the third metal layer M3. The connection vias S1 include a first connection via S11 and a third connection via S13. In the thickness direction of the display panel, a first connection via S11 at least partially overlaps with a third connection via S13 so that the first connection via S11 communicates with the third connection via S13 through the first bridging structure 400. The data signal connection lines 202b are electrically connected to the first bridging structure 400 through the first connection via S11, and the first bridging structure 400 is electrically connected to the data signal transmission lines 202a through the third connection via S13. Thus, the electrical connection between the data signal transmission lines 202a located in the second metal layer M2 and the data signal connection lines 202b located in the fourth metal layer M4 is achieved through the first bridging structure 400, the first connection via S11, and the third connection via S13, thereby ensuring a simple connection between the data signal transmission lines 202a and the data signal connection lines 202b.

It should be noted that a second buffer layer 014 and a gate insulating layer 015 may also be included between the substrate 10 and the first metal layer M1. The second buffer layer 014 is located on a side of the gate insulating layer 015 facing the substrate 10, and the first metal layer M1 is disposed on the gate insulating layer 015. Furthermore, multiple interlayer insulating layers are provided between the fourth metal layer M4 and the first metal layer M1, such as a first interlayer insulating layer 016 and a second interlayer insulating layer 017. The first interlayer insulating layer 016 is located on a side of the second interlayer insulating layer 017 facing the substrate 10. The first bridging structure 400 penetrates through at least part of the interlayer insulating layers. In the implementation shown in FIG. 9, the first bridging structure 400 penetrates through the second interlayer insulating layer 017 and part of the first interlayer insulating layer 016. In the implementation shown in FIG. 17, the first bridging structure 400 penetrates through part of the second interlayer insulating layer 017. Furthermore, the display panel further includes a passivation layer 018 covering part of the second interlayer insulating layer 017 and part of the first bridging structure 400. That is, the first connection via S11 and the second connection via S12, or the first connection via S11 and the third connection via S13, connected by the first bridging structure 400 are covered by the interlayer insulating layers and the passivation layer 018, thereby avoiding erosion from reactive ions. It should be understood that a dielectric layer 019 is also disposed between the substrate 10 and the fourth metal layer M4. The dielectric layer 019 serves functions such as signal isolation, parasitic capacitance control, and stress buffering. Moreover, a planarization layer 020 is also provided on a side of the fourth metal layer M4 facing away from the substrate 10. The planarization layer 020 optimizes film layer flatness, thereby providing a foundation for subsequent device fabrication.

Embodiments of the present application further provide a display panel. FIG. 18 illustrates yet another section view taken along the direction C-C′ of the display panel illustrated in FIG. 1. Referring to FIGS. 1 and 18, the display panel includes a display region AA and a non-display region BB, and the non-display region BB is located on at least one side of the display region AA. The display region AA may include multiple light-emitting elements and a pixel circuit. The pixel circuit is electrically connected to the light-emitting elements, and various drive signals are provided for the light-emitting elements through the pixel circuit to drive the light-emitting elements to emit light, thereby achieving the image display in the display region AA. The non-display region BB includes a bending region BB1 and a first via transition region BB2, and the first via transition region BB2 is located on a side of the bending region BB1 facing the display region AA. In an example, the lower bezel region of the non-display region BB may include a bending region BB1 and a first via transition region BB2. The first via transition region BB2 is located on a side of the bending region BB1 facing the display region AA, that is, the first via transition region BB2 is located between the bending region BB1 and the display region AA. It should be understood that the first via transition region BB2 may be the junction between the bending region BB1 and the display region AA. As shown in FIG. 18, the display panel further includes a substrate 10 and a signal routing 20 located on a side of the substrate 10. The signal routing 20 may be a data signal routing connected to the pixel circuit and may also serve as a signal routing in the left bezel region and/or the right bezel region, such as a gate signal routing connected to the gate driver circuit. The signal routing 20 includes signal transmission lines 210 and signal connection lines 220 arranged in different layers. The signal connection lines 220 are located on a side of the signal transmission lines 210 facing away from the substrate 10. In an example, the signal transmission lines 210 may be electrically connected to the pixel circuit located in the display region AA or the gate driver circuit located in the left bezel region and/or the right bezel region, and the signal connection lines 220 may be electrically connected to the driver chip located in the bending region BB1. Furthermore, the signal transmission lines 210 and the signal connection lines 220 are electrically connected through at least one connection via S1 in the first via transition region BB2 to disperse the bending stress of the bending region BB1 when bent through the at least one connection via S1.

Moreover, the display panel further includes a first shielding structure 310. The first shielding structure 310 is located on a side of the signal connection lines 220 facing away from the substrate 10, and in a thickness direction of the display panel, the first shielding structure 310 at least partially overlaps with the first via transition region BB2. The physical blocking effect of the first shielding structure 310 blocks reactive ions from reaching the connection via S1, and the reactive ions are prevented from reacting with the material of the at least one connection via S1 in the first via transition region BB2 and corroding the at least one connection via S1, which otherwise leads to poor connection stability between the signal connection lines 220 and the signal transmission lines 210 and results in display abnormalities, thereby alleviating the corrosion in the first via transition region BB2 and improving the display performance of the display panel.

Additionally, the first shielding structure 310 further includes a second shielding layer 312. The display panel further includes a pixel defining layer 110 and an iodine-based polarizer layer 40. The second shielding layer 312 is located on a side of the pixel defining layer 110 facing away from the substrate 10, that is, the second shielding layer 312 is located between the pixel defining layer 110 and the iodine-based polarizer layer 40. Thus, while the second shielding layer 312 blocks reactive ions from reaching the connection via S1, the second shielding layer 312 can also prevent hydroxide ions beneath the second shielding layer 312 from reacting with elemental iodine released by the iodine-based polarizer layer 40 to reduce the generation of iodide ions, thereby further reducing the number of iodide ions reaching the connection via S1 and alleviating the corrosion in the first via transition region BB2.

On the basis of the above, still referring to FIG. 18, the display panel further includes at least one touch metal layer 70. The at least one touch metal layer 70 is located on a side of the pixel defining layer 110 facing away from the substrate 10. The second shielding layer 312 is disposed in the same layer as the at least one touch metal layer 70 and is insulated from the at least one touch metal layer 70.

In one or more embodiments, since the touch metal layer 70 is located between the pixel defining layer 110 and the iodine-based polarizer layer 40, the second shielding layer 312 may be arranged in the same layer as, yet insulated from, the at least one touch metal layer 70. Thus, while the second shielding layer 312 blocks reactive ions from reaching the connection via S1, the second shielding layer 312 can also prevent hydroxide ions beneath the second shielding layer 312 from reacting with elemental iodine released by the iodine-based polarizer layer 40 to reduce the generation of iodide ions, thereby further reducing the number of iodide ions reaching the connection via S1 and alleviating the corrosion in the first via transition region BB2. Furthermore, since the second shielding layer 312 is disposed in the same layer as the at least one touch metal layer 70, the second shielding layer 312 and the at least one touch metal layer 70 can be fabricated in the same process step using a single mask during manufacturing, and the need for separate masks for the second shielding layer 312 and the at least one touch metal layer 70 is eliminated, thereby reducing costs, decreasing the number of process steps, and improving production efficiency.

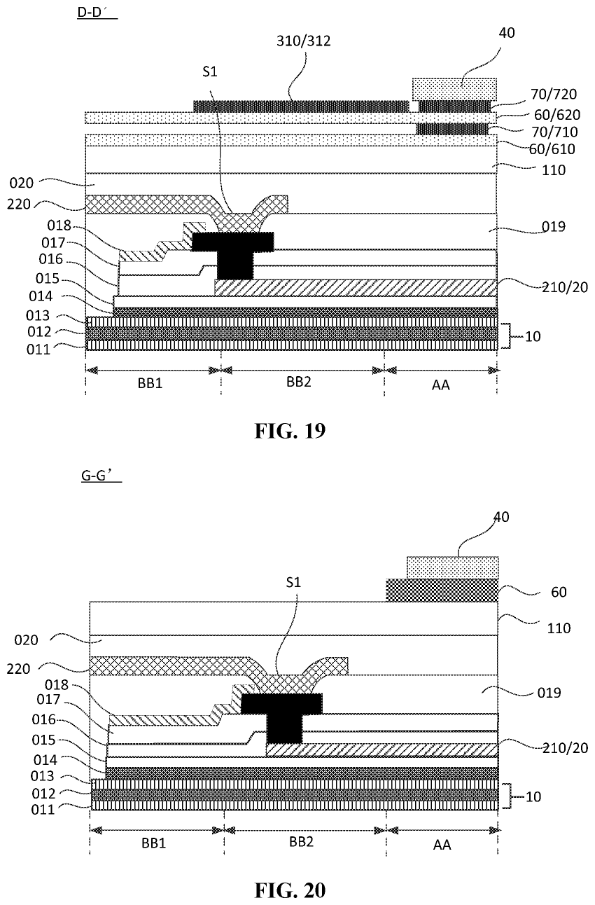

In one or more embodiments, on the basis of the preceding embodiments, FIG. 19 illustrates yet another section view taken along the direction D-D′ of the display panel illustrated in FIG. 1. Referring to FIGS. 18 and 19, the display panel further includes a silicon-nitride-based inorganic layer 60 located on a side of the signal connection lines 220 facing away from the substrate 10. The at least one touch metal layer 70 includes a first touch metal layer 710 and a second touch metal layer 720. The silicon-nitride-based inorganic layer 60 includes a first inorganic layer 610 and a second inorganic layer 620. The first inorganic layer 610 is located on a side of the second inorganic layer 620 facing the substrate 10. The first touch metal layer 710 is located between the first inorganic layer 610 and the second inorganic layer 620. The second touch metal layer 720 is located on a side of the silicon-nitride-based inorganic layer 60 facing away from the substrate 10. In the thickness direction of the display panel, the first touch metal layer 710 covers the first inorganic layer 610, and the second touch metal layer 720 covers the silicon-nitride-based inorganic layer 60. The second shielding layer 312 is disposed in the same layer as the first touch metal layer 710 and is insulated from the first touch metal layer 710 and/or the second shielding layer 312 is disposed in the same layer as the second touch metal layer 720 and is insulated from the second touch metal layer 720.

In one or more embodiments, the silicon-nitride-based inorganic layer 60 is located on the surface of the pixel defining layer 110 facing away from the substrate 10. The light-emitting element within the pixel defining layer 110 is prevented from moisture and oxygen erosion through the silicon-nitride-based inorganic layer 60, thereby protecting the light-emitting element. It should be noted that the inorganic layer includes a silicon-nitride-based inorganic layer and a silicon-oxide-based inorganic layer, and the dielectric constant of the silicon-nitride-based inorganic layer is higher than the dielectric constant of the silicon-oxide-based inorganic layer. Typically, a silicon-nitride-based inorganic layer 60 is prepared on a side of the pixel defining layer 110 facing away from the substrate 10. However, ammonia gas is introduced during the preparation of the silicon-nitride-based inorganic layer 60, and under certain conditions, the ammonia gas reacts with water vapor to generate hydroxide ions. Meanwhile, the iodine-based polarizer layer 40 located on a side of the silicon-nitride-based inorganic layer 60 facing away from the substrate 10 precipitates elemental iodine under certain conditions, and iodide ions generated from the reaction between the elemental iodine and hydroxide ions may corrode the connection via S1. Therefore, in the embodiments of the present application, the final generation of iodide ions is reduced by arranging the second shielding layer 312 between the pixel defining layer 110 and the iodine-based polarizer layer 40.

In an example, in the implementation shown in FIG. 18, in the thickness direction of the display panel, the first touch metal layer 710 covers the first inorganic layer 610, and the second shielding layer 312 is disposed in the same layer as the first touch metal layer 710. On one hand, the first touch metal layer 710 covering the first inorganic layer 610 and the second shielding layer 312 can block hydroxide ions generated from the reaction between ammonia gas and water vapor from reacting with elemental iodine released by the iodine-based polarizer layer 40, thereby reducing the generation of iodide ions. On the other hand, the second shielding layer 312 at least partially overlapping with the first via transition region BB2 can also block iodide ions from reaching the connection via S1, thereby further alleviating the corrosion in the first via transition region BB2.

In another embodiment, in the implementation shown in FIG. 19, in the thickness direction of the display panel, the second touch metal layer 720 covers the second inorganic layer 620, and the second shielding layer 312 is disposed in the same layer as the second touch metal layer 720. On one hand, the second touch metal layer 720 covering the second inorganic layer 620 and the second shielding layer 312 can block hydroxide ions generated from the reaction between ammonia gas and water vapor from reacting with elemental iodine released by the iodine-based polarizer layer 40, thereby reducing the generation of iodide ions. On the other hand, the second shielding layer 312 at least partially overlapping with the first via transition region BB2 can also block the ultimately generated iodide ions from reaching the connection via S1, thereby further alleviating the corrosion in the first via transition region BB2.

It should be noted that FIGS. 18 and 19 merely illustrate an example where the second shielding layer 312 is arranged in the same layer as one touch metal layer, but the present application is not limited thereto. In other embodiments, the second shielding layer 312 may include two shielding layers that are arranged in the same layers as two touch metal layers, respectively, and those skilled in the art may make corresponding configurations of the second shielding layer 312 according to actual requirements.

Embodiments of the present application further provide a display panel. FIG. 20 illustrates a section view taken along the direction G-G′ of the display panel illustrated in FIG. 1. Referring to FIGS. 1 and 20, the display panel includes a display region AA and a non-display region BB, and the non-display region BB is located on at least one side of the display region AA. The non-display region BB includes a bending region BB1 and a first via transition region BB2, and the first via transition region BB2 is located on a side of the bending region BB1 facing the display region AA. The display panel further includes a substrate 10 and a signal routing 20 located on a side of the substrate 10. The signal routing 20 includes signal transmission lines 210 and signal connection lines 220 arranged in different layers, and the signal connection lines 220 are located on a side of the signal transmission lines 210 facing away from the substrate 10. The signal transmission lines 210 and the signal connection lines 220 are electrically connected through at least one connection via S1 in the first via transition region BB2. The display panel further includes a silicon-nitride-based inorganic layer 60 located on a side of the signal connection lines 220 facing away from the substrate 10. The silicon-nitride-based inorganic layer 60 is staggered from the first via transition region BB2 in the thickness direction of the display panel.

In an example, as shown in FIG. 1, the display panel includes a display region AA and a non-display region BB. The display region AA may include multiple light-emitting elements and a pixel circuit. The pixel circuit is electrically connected to the light-emitting elements, and various drive signals are provided for the light-emitting elements through the pixel circuit to drive the light-emitting elements to emit light, thereby achieving the image display in the display region AA. The non-display region BB surrounds at least a part of the display region AA. In an example, the non-display region BB may be the bezel region of the display panel. For example, the non-display region BB may include an upper bezel region, a lower bezel region, a left bezel region, and a right bezel region. The left bezel region and/or the right bezel region may be provided with a gate driver circuit. The lower bezel region may include a bending region BB1 and a first via transition region BB2. The first via transition region BB2 is located on a side of the bending region BB1 facing the display region AA, that is, the first via transition region BB2 is located between the bending region BB1 and the display region AA. It should be understood that the first via transition region BB2 may be the junction between the bending region BB1 and the display region AA.

In an example, in the implementation shown in FIG. 20, the display panel further includes a substrate 10 and a signal routing 20 located on a side of the substrate 10. The substrate 10 may include a stacked structure composed of a first flexible base layer 011, a first buffer layer 012, and a second flexible base layer 013. The materials of the first flexible base layer 011 and the second flexible base layer 013 may include polyimide (PI). PI has excellent flexibility, bending resistance, and certain high temperature resistance and thus provides a physical basis for bending and curling of subsequent processes and final products. The signal routing 20 may be a data signal routing connected to the pixel circuit and may also serve as a signal routing in the left bezel region and/or the right bezel region, such as a gate signal routing connected to the gate driver circuit. The present application is not limited thereto, and those skilled in the art may make corresponding configurations of the signal routing 20 according to actual requirements. One end of the data signal routing is electrically connected to the pixel circuit in the display region AA, and the other end is electrically connected to a driver chip located in the bending region BB1. Similarly, one end of the gate signal routing is electrically connected to the gate driver circuit in the left bezel region and/or the right bezel region, and the other end is electrically connected to the driver chip located in the bending region BB1, so that various drive signals may be provided through the driver chip. As can be seen from the above, the signal routing 20 extends from the display region AA or the left and right bezel regions to the driver chip in the bending region BB1 and is bent in the bending region BB1 to a non-light-emitting side of the display panel. Furthermore, by arranging the signal routing 20 to undergo layer switching at the junction, that is, the first via transition region BB2, between the bending region BB1 and the display region AA, the signal routing 20 includes signal transmission lines 210 and signal connection lines 220 arranged in different layers, and The signal transmission lines 210 and the signal connection lines 220 are electrically connected through at least one connection via S1 in the first via transition region BB2. Thus, the bending stress experienced by the bending region BB1 when bent is dispersed through the at least one connection via S1.

Furthermore, the display panel further includes a silicon-nitride-based inorganic layer 60 located on a side of the signal connection lines 220 facing away from the substrate 10. In one or more embodiments, the silicon-nitride-based inorganic layer 60 is located on the surface of the pixel defining layer 110 facing away from the substrate 10. The light-emitting element within the pixel defining layer 110 is prevented from moisture and oxygen erosion through the silicon-nitride-based inorganic layer 60, thereby protecting the light-emitting element. It should be noted that the inorganic layer includes a silicon-nitride-based inorganic layer and a silicon-oxide-based inorganic layer, and the dielectric constant of the silicon-nitride-based inorganic layer is higher than the dielectric constant of the silicon-oxide-based inorganic layer. Typically, a silicon-nitride-based inorganic layer with a higher dielectric constant is prepared on the pixel defining layer 110. On one hand, the silicon-nitride-based inorganic layer has a denser structure and superior blocking properties compared to the silicon-oxide-based inorganic layer and thus can effectively block moisture and oxygen from the air. On the other hand, the silicon-nitride-based inorganic layer having a higher dielectric constant can provide better performance during the subsequent fabrication of other components. However, ammonia gas is introduced during the preparation of the silicon-nitride-based inorganic layer 60, and under certain conditions, the ammonia gas reacts with water vapor to generate hydroxide ions. Meanwhile, the iodine-based polarizer layer 40 located on a side of the silicon-nitride-based inorganic layer 60 facing away from the substrate 10 precipitates elemental iodine under certain conditions, and iodide ions generated from the reaction between the elemental iodine and hydroxide ions may corrode the connection via S1.

Therefore, in the embodiments of the present application, the silicon-nitride-based inorganic layer 60 is arranged to avoid the first via transition region BB2, that is, the silicon-nitride-based inorganic layer 60 is staggered from the first via transition region BB2 in the thickness direction of the display panel. Since the silicon-nitride-based inorganic layer 60 is not prepared in the first via transition region BB2, the amount of ammonia gas introduced in the first via transition region BB2 is reduced, thereby decreasing the number of generated hydroxide ions. Thus, although the iodine-based polarizer layer 40 may still release elemental iodine under certain conditions, the decreased number of hydroxide ions leads to a corresponding reduction in the number of iodide ions ultimately generated. From another perspective, consequently, the number of iodide ions reaching the connection via S1 is reduced, thereby further alleviating the corrosion in the first via transition region BB2.

In summary, in the embodiments of the present application, by arranging the silicon-nitride-based inorganic layer to be staggered from the first via transition region in the thickness direction of the display panel, the silicon-nitride-based inorganic layer when prepared avoids the first via transition region, and the amount of ammonia gas introduced in the first via transition region is reduced, thereby decreasing the number of generated hydroxide ions. Thus, although the iodine-based polarizer layer may still release elemental iodine under certain conditions, the decreased number of hydroxide ions leads to a corresponding reduction in the number of iodide ions ultimately generated, and the number of iodide ions reaching the connection via is reduced consequently, thereby alleviating the corrosion in the first via transition region.

In one or more embodiments, on the basis of the preceding embodiments, still referring to FIG. 6, the display panel further includes a first shielding structure 310. The first shielding structure 310 is located on a side of the signal connection lines 220 facing away from the substrate 10, and in a thickness direction of the display panel, the first shielding structure 310 at least partially overlaps with the first via transition region BB2. The physical blocking effect of the first shielding structure 310 blocks reactive ions from reaching the connection via S1, and the reactive ions are prevented from reacting with the material of the at least one connection via S1 in the first via transition region BB2 and corroding the connection via S1, which otherwise leads to poor connection stability between the signal connection lines 220 and the signal transmission lines 210 and results in display abnormalities, thereby alleviating the corrosion in the first via transition region BB2 and improving the display performance of the display panel.

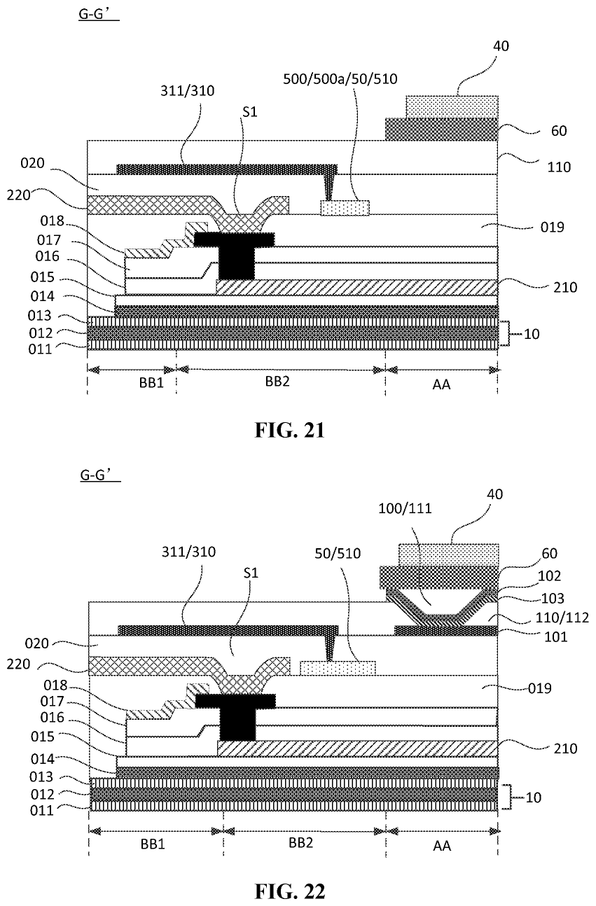

In one or more embodiments, on the basis of the preceding embodiments, FIG. 21 illustrates another section view taken along the direction G-G′ of the display panel illustrated in FIG. 1. Referring to FIG. 21, the first shielding structure 310 is electrically connected to a potential signal line 500. In one or more embodiments, the first shielding structure 310 may be a conductive structure. By electrically connecting the first shielding structure 310 to the potential signal line 500, the potential signal line 500 provides a fixed potential signal or a jumping potential signal for the first shielding structure 310. Thus, in addition to the physical blocking effect of the first shielding structure 310 against reactive ions, a potential signal is applied to the first shielding structure 310. The charged first shielding structure 310 can attract or repel the reactive ions to further block the reactive ions from reaching the connection via S1, thereby further alleviating the corrosion in the first via transition region BB2 and improving the display performance of the display panel.

On the basis of the preceding embodiments, the first shielding structure 310 is electrically connected to a fixed potential signal line 500a. In one or more embodiments, the signal transmitted in the fixed potential signal line 500a is a fixed potential signal. By electrically connecting the first shielding structure 310 to the fixed potential signal line 500a, the potential signal on the first shielding structure 310 becomes a fixed potential signal. Thus, the force exerted by the first shielding structure 310 on the reactive ions is consistently either repulsive or attractive. For example, when the reactive ions are negatively charged, the fixed potential signal on the first shielding structure 310 may be set to a positive fixed potential signal to attract the reactive ions to the first shielding structure 310, thereby reducing the number of reactive ions reaching the connection via S1 and alleviating the corrosion in the first via transition region BB2. Conversely, when the reactive ions are positively charged, the fixed potential signal on the first shielding structure 310 may be set to a negative fixed potential signal. Since the reactive ions typically enter from a side of the signal routing 20 facing away from the substrate 10, the repulsive force exerted by the first shielding structure 310 located on the signal routing 20 against the reactive ions can reduce the number of reactive ions that ultimately reach the at least one connection via S1, thereby alleviating the corrosion in the first via transition region BB2. Similarly, when the reactive ions are negatively charged, the fixed potential signal on the first shielding structure 310 may also be set to a positive potential signal. When the reactive ions are positively charged, the fixed potential signal on the first shielding structure 310 may also be set to a negative potential signal. Thus, by electrically connecting the first shielding structure 310 to the fixed potential signal line 500a, a continuous repulsive or attractive force can be applied to the reactive ions, thereby further reducing the number of reactive ions reaching the connection via S1 and alleviating the corrosion in the first via transition region BB2.

In one or more embodiments, still referring to FIG. 21, the display panel further includes an iodine-based polarizer layer 40 located on a side of the silicon-nitride-based inorganic layer 60 facing away from the substrate 10. The display panel further includes a power supply routing 50 located on a side of the substrate 10. The power supply routing includes a first power supply routing 510. The first shielding structure 310 is electrically connected to the first power supply routing 510. The first power supply routing 510 is arranged to provide a negative fixed potential signal for the first shielding structure 310.

In an example, in the implementation shown in FIG. 21, the display panel further includes an iodine-based polarizer layer 40. The iodine-based polarizer layer 40 at least partially overlaps with the display region AA in the thickness direction of the display panel, thereby improving the light output effect of the display region AA through the iodine-based polarizer layer 40. Moreover, the iodine-based polarizer layer 40 is located on a side of the first shielding structure 310 facing away from the signal routing 20, that is, the first shielding structure 310 is located between the iodine-based polarizer layer 40 and the connection via S1. Thus, when the iodine-based polarizer layer 40 precipitates elemental iodine under certain conditions and ammonia gas introduced during the preparation of the silicon-nitride-based inorganic layer reacts with water vapor to generate hydroxide ions under certain conditions, the iodide ions generated from the reaction between the elemental iodine and hydroxide ions are blocked by the first shielding structure 310, thereby reducing the number of iodide ions reaching the connection via S1 and alleviating the corrosion in the first via transition region BB2. Furthermore, the display panel further includes a power supply routing 50 located on a side of the substrate 10. The power supply routing 50 includes a first power supply routing 510. The first power supply routing 510 is arranged to provide a negative fixed potential signal. For example, as shown in FIG. 21, the first power supply routing 510 may be disposed in the same layer as the signal connection lines 220. By electrically connecting the first shielding structure 310 to the first power supply routing 510, the first power supply routing 510 provides a negative fixed potential signal for the first shielding structure 310. Since iodide ions are themselves negatively charged, the first shielding structure 310 exerts a repulsive force on the iodide ions, thereby further reducing the number of reactive ions that ultimately reach the at least one connection via S1 and alleviating the corrosion in the first via transition region BB2.

It should be noted that the implementation shown in FIG. 21 describes the first power supply routing 510 being disposed in the same film layer as the signal connection lines 220 as an example, but the present application is not limited thereto. In other embodiments, the first power supply routing 510 may also be disposed in a film layer other than the film layer where the signal connection lines 220 are located.

In one or more embodiments, in another embodiment, still referring to FIG. 6, the display panel further includes an iodine-based polarizer layer 40 located on a side of the silicon-nitride-based inorganic layer 60 facing away from the substrate 10. The display panel further includes a power supply routing 50 located on a side of the substrate 10. The power supply routing includes a second power supply routing 520. The first shielding structure 310 is electrically connected to the second power supply routing 520. The second power supply routing 520 is arranged to provide a positive fixed potential signal for the first shielding structure 310.

In one or more embodiments, as shown in FIG. 6, the display panel further includes an iodine-based polarizer layer 40. The iodine-based polarizer layer 40 at least partially overlaps with the display region AA in the thickness direction of the display panel, thereby improving the light output effect of the display region AA through the iodine-based polarizer layer 40. Moreover, the iodine-based polarizer layer 40 is located on a side of the first shielding structure 310 facing away from the signal routing 20, that is, the first shielding structure 310 is located between the iodine-based polarizer layer 40 and the at least one connection via S1. Thus, when the iodine-based polarizer layer 40 precipitates elemental iodine under certain conditions and ammonia gas introduced during the preparation of the silicon-nitride-based inorganic layer reacts with water vapor to generate hydroxide ions under certain conditions, the iodide ions generated from the reaction between the elemental iodine and hydroxide ions are blocked by the first shielding structure 310, thereby reducing the number of iodide ions reaching the connection via S1 and alleviating the corrosion in the first via transition region BB2. Furthermore, the display panel further includes a power supply routing 50 located on a side of the substrate 10. The power supply routing 50 includes a second power supply routing 520. The second power supply routing 520 is arranged to provide a positive fixed potential signal. In an example, as shown in FIG. 6, the second power supply routing 520 may be disposed in the same layer as the signal connection lines 220. By electrically connecting the first shielding structure 310 to the second power supply routing 520, the second power supply routing 520 provides a positive fixed potential signal for the first shielding structure 310. Since iodide ions are themselves negatively charged, the first shielding structure 310 exerts an attractive force on the iodide ions, thereby reducing the number of reactive ions that ultimately reach the at least one connection via S1 and alleviating the corrosion in the first via transition region BB2.

It should be noted that the implementation shown in FIG. 6 describes the second power supply routing 520 being disposed in the same film layer as the signal connection lines 220 as an example, but the present application is not limited thereto. In other embodiments, the second power supply routing 520 may also be disposed in a film layer other than the film layer where the signal connection lines 220 are located.

In one or more embodiments, on the basis of the preceding embodiments, FIG. 22 illustrates yet another section view taken along the direction G-G′ of the display panel illustrated in FIG. 1. Referring to FIG. 22, the first shielding structure 310 includes a first shielding layer 311. The display panel further includes a pixel defining layer 110, and the first shielding layer 311 is located between the film layer where the signal connection lines 220 are located and the film layer where the pixel defining layer 110 is located.

In an example, in the implementation shown in FIG. 22, the display panel further includes a pixel defining layer 110. The portion of the pixel defining layer 110 located in the display region AA includes a pixel opening section 111 and a pixel defining section 112. The pixel defining section 112 is arranged surrounding the pixel opening section 111. Furthermore, the pixel defining layer 110 is located on a side of the signal connection lines 220 facing away from the substrate 10, and at least one planarization layer is interposed between the pixel defining layer 110 and the signal connection lines 220. By providing the first shielding layer 311 between the film layer where the signal connection lines 220 are located and the film layer where the pixel defining layer 110 is located, the distance between the first shielding layer 311 and the at least one connection via S1 in the thickness direction of the display panel is reduced, thereby further enhancing the physical blocking effect of the first shielding layer 311 against reactive ions and further alleviating the corrosion in the first via transition region BB2.

In one or more embodiments, on the basis of the preceding embodiments, still referring to FIG. 22, the display panel further includes a light-emitting element 100. The light-emitting element 100 includes a first electrode 101. The opening in the pixel defining layer 110 is arranged to expose at least a portion of the first electrode 101. The first electrode 101 is located in the display region AA, and the film layer where the first electrode 101 is located is located between the film layer where the signal connection lines 220 are located and the film layer where the pixel defining layer 110 is located. The first shielding structure 310 is disposed in the same layer as the first electrode 101 and is insulated from the first electrode 101.

In one or more embodiments, a light-emitting element 100 is disposed within the pixel opening section 111 in the display region AA. The light-emitting element 100 includes a first electrode 101, a second electrode 102, and a common light-emitting layer 103. The common light-emitting layer 103 is located within the pixel opening section 111. The second electrode 102 may serve as the cathode of the light-emitting element 100, and the first electrode 101 may serve as the anode of the light-emitting element 100. The common light-emitting layer 103 is located between the first electrode 101 and the second electrode 102. The first electrode 101 is electrically connected to the pixel circuit. The common light-emitting layer 103 may include multiple layers, such as a hole injection layer, a hole transport layer, a light-emitting layer, an electron transport layer, and an electron injection layer, that are arranged in a stacked manner. When no voltage is applied across the first electrode 101 and the second electrode 102, the light-emitting element 100 does not emit light. When a voltage is applied across the first electrode 101 and the second electrode 102, the first electrode injects holes into the hole injection layer, and the second electrode injects electrons into the electron injection layer. The holes and the electrons recombine in the light-emitting layer to form excitons, thereby resulting in radiative light emission. On the basis of the above, since the film layer where the first electrode 101 is located is located between the film layer where the signal connection lines 220 are located and the film layer where the pixel defining layer 110 is located, the first shielding structure 310 may be provided in the same layer as the first electrode 101 and is insulated from the first electrode 101. Thus, the first shielding layer 311 may be provided closer to the connection via S1 in the thickness direction of the display panel, thereby enhancing the physical blocking effect of the first shielding structure 311 against reactive ions and alleviating the corrosion in the first via transition region BB2. Moreover, since the first shielding structure 310 and the first electrode 101 are located in the same film layer, the first shielding structure 310 and the first electrode 101 can be fabricated in the same process step using a single mask during manufacturing, and the need for separate masks for the first shielding structure 310 and the first electrode 101 is eliminated, thereby reducing costs, decreasing the number of process steps, and improving production efficiency.

In one or more embodiments, on the basis of the preceding embodiments, FIG. 23 illustrates yet another section view taken along the direction G-G′ of the display panel illustrated in FIG. 1. Referring to FIG. 23, the first shielding structure 310 includes a second shielding layer 312. The display panel further includes a pixel defining layer 110, and the second shielding layer 312 is located on a side of the pixel defining layer 110 facing away from the substrate 10.

In one or more embodiments, the first shielding structure 310 further includes a second shielding layer 312. The display panel further includes a pixel defining layer 110 and an iodine-based polarizer layer 40. The second shielding layer 312 is located on a side of the pixel defining layer 110 facing away from the substrate 10, that is, the second shielding layer 312 is located between the pixel defining layer 110 and the iodine-based polarizer layer 40. Thus, while the second shielding layer 312 blocks reactive ions from reaching the connection via S1, the second shielding layer 312 can also prevent hydroxide ions beneath the second shielding layer 312 from reacting with elemental iodine released by the iodine-based polarizer layer 40 to reduce the generation of iodide ions, thereby further reducing the number of iodide ions reaching the connection via S1 and alleviating the corrosion in the first via transition region BB2.

In one or more embodiments, still referring to FIG. 23, the display panel further includes at least one touch metal layer 70. The at least one touch metal layer 70 is located on a side of the pixel defining layer 110 facing away from the substrate 10. The second shielding layer 312 is disposed in the same layer as the at least one touch metal layer 70 and is insulated from the at least one touch metal layer 70.

In one or more embodiments, in the implementation shown in FIG. 23, the at least one touch metal layer 70 may extend from the display region AA to the first via transition region BB2. Since no silicon-nitride-based inorganic layer 60 is provided above the first via transition region BB2, the portion of the at least one touch metal layer 70 located on the surface of the silicon-nitride-based inorganic layer 60 overlaps with the display region AA in the thickness direction of the display panel, and the portion of the at least one touch metal layer 70 located on the surface of the pixel defining layer 110 at least partially overlaps with the first via transition region BB2 in the thickness direction of the display panel. That is, the portion of the at least one touch metal layer 70 located on the surface of the pixel defining layer 110 can serve as the second shielding layer 312. Thus, while the second shielding layer 312 blocks reactive ions from reaching the connection via S1, the second shielding layer 312 can also prevent hydroxide ions beneath the second shielding layer 312 from reacting with elemental iodine released by the iodine-based polarizer layer 40 to reduce the generation of iodide ions, thereby further reducing the number of iodide ions reaching the connection via S1 and alleviating the corrosion in the first via transition region BB2. Furthermore, since the second shielding layer 312 is disposed in the same layer as the at least one touch metal layer 70, the second shielding layer 312 and the at least one touch metal layer 70 can be fabricated in the same process step using a single mask during manufacturing, and the need for separate masks for the second shielding layer 312 and the at least one touch metal layer 70 is eliminated, thereby reducing costs, decreasing the number of process steps, and improving production efficiency.

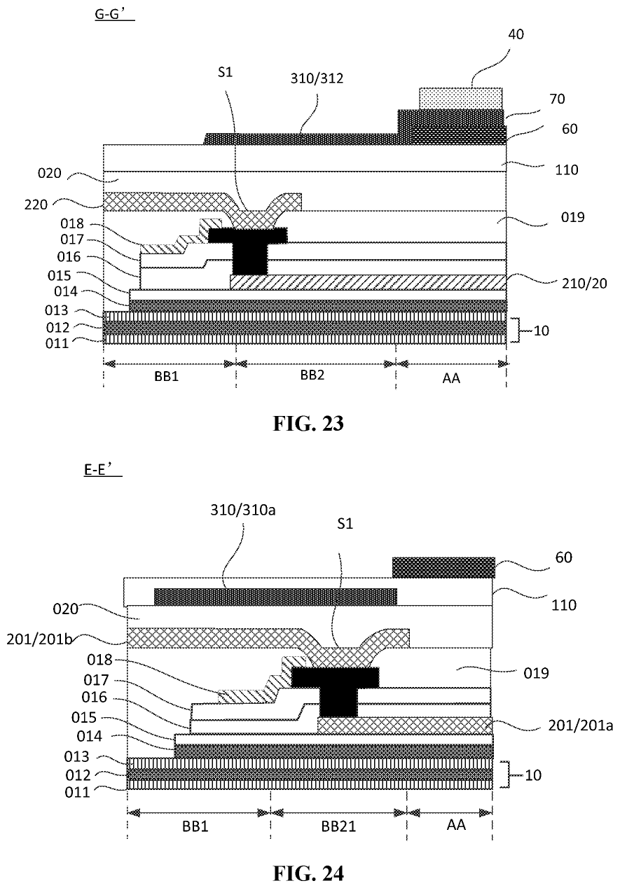

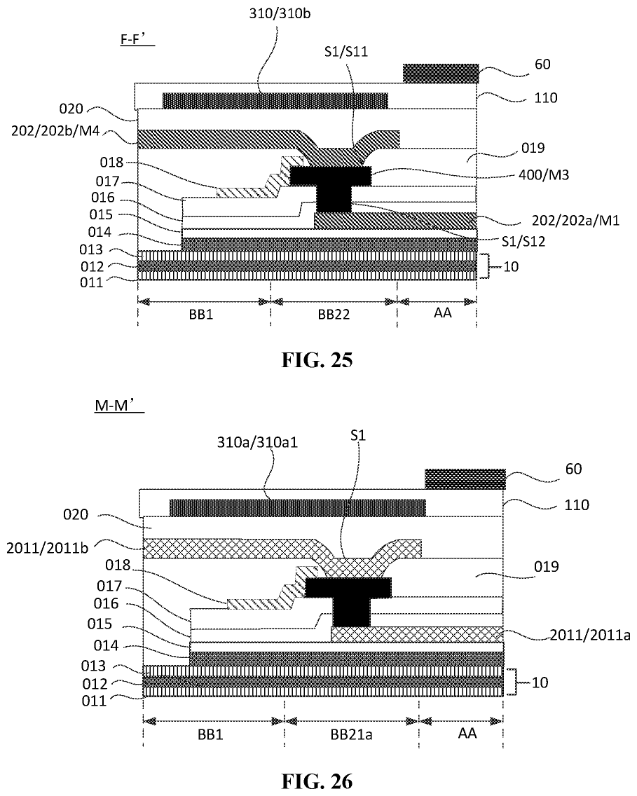

In one or more embodiments, on the basis of the preceding embodiments, FIG. 24 illustrates another section view taken along the direction E-E′ of the non-display region illustrated in FIG. 7, and FIG. 25 illustrates yet another section view taken along the direction F-F′ of the non-display region illustrated in FIG. 7. Referring to FIGS. 7, 24, and 25, the signal routing 20 includes a gate signal routing 201 and a data signal routing 202. The first via transition region BB2 includes a gate line via transition region BB21 and a data line via transition region BB22. The gate signal routing 201 includes gate signal transmission lines 201a and gate signal connection lines 201b arranged in different layers. The gate signal connection lines 201b are located on a side of the gate signal transmission lines 201a facing away from the substrate 10, and the gate signal transmission lines 201a and the gate signal connection lines 201b are electrically connected through at least one connection via S1 in the gate line via transition region BB21. The data signal routing 202 includes data signal transmission lines 202a and data signal connection lines 202b arranged in different layers. The data signal connection lines 202b are located on a side of the data signal transmission lines 202a facing away from the substrate 10, and the data signal transmission lines 202a and the data signal connection lines 202b are electrically connected through at least one connection via S1 in the data line via transition region BB22. The first shielding structure 310 includes a gate shielding structure section 310a and a data shielding structure section 310b. In the thickness direction of the display panel, the gate shielding structure section 310a at least partially overlaps with the gate line via transition region BB21, and the data shielding structure section 310b at least partially overlaps with the data line via transition region BB22.

In one or more embodiments, as shown in FIG. 7, the lower bezel region of the display panel includes multiple signal routings 20 and multiple power supply routings 50. The signal routing 20 may include a gate signal routing 201 and a data signal routing 202. The power supply routing 50 may include a first power supply routing 510 and a second power supply routing 520. The first power supply routing 510 may transmit a negative fixed potential signal, and the second power supply routing 520 may transmit a positive fixed potential signal. Assuming the direction from the first via transition region BB2 toward the bending region BB1 is defined as a first direction X and a second direction Y intersects the first direction X, the power supply routings 50 and the signal routings 20 extend in the first direction X and are arranged in the second direction Y. Since one end of the gate signal routing 201 is electrically connected to the gate driver circuit in the left bezel region and/or the right bezel region, the gate signal routing 201 is located at the edge of the lower bezel region in the second direction Y to facilitate the electrical connection to the gate driver circuit. The first power supply routing 510 is arranged surrounding at least a portion of the display region AA. Therefore, by arranging the first power supply routing 510 at the edge of the lower bezel region in the second direction Y, the routing of the first power supply routing 510 is made more convenient. One end of the data signal routing 202 is electrically connected to the pixel circuit in the display region AA, and thus, all the data signal routings 202 can be concentrated in the central region of the lower bezel region for routing.

On the basis of the above, referring to FIGS. 7 and 24, the first via transition region BB2 includes a gate line via transition region BB21. The gate line via transition region BB21 is located on a side of the bending region BB1 facing the display region AA. The gate signal routing 201 includes gate signal transmission lines 201a and gate signal connection lines 201b arranged in different layers. The gate signal connection lines 201b are located on a side of the gate signal transmission lines 201a facing away from the substrate 10. The gate signal connection lines 201b may be electrically connected to the driver chip located in the bending region BB1, and the gate signal transmission lines 201a may be electrically connected to the gate driver circuit located in the left bezel region and/or the right bezel region. The gate signal transmission lines 201a and the gate signal connection lines 201b are electrically connected through at least one connection via S1 in the gate line via transition region BB21 to disperse the bending stress experienced by the bending region BB1 when bent. The first shielding structure 310 includes a gate shielding structure section 310a, and the gate shielding structure section 310a at least partially overlaps with the gate line via transition region BB21 in the thickness direction of the display panel. Thus, the gate shielding structure section 310a blocks reactive ions from reaching the connection via S1 in the gate line via transition region BB21, and the reactive ions are prevented from reacting with the material of the connection via S1 in the gate line via transition region BB21 and corroding the connection via S1, thereby alleviating the corrosion phenomenon in the gate line via transition region BB21 and improving the display performance of the display panel.

On the basis of the above, referring to FIGS. 7 and 25, the first via transition region BB2 further includes a data line via transition region BB22. The data line via transition region BB22 is located on a side of the bending region BB1 facing the display region AA. The data signal routing 202 includes data signal transmission lines 202a and data signal connection lines 202b arranged in different layers. The data signal connection lines 202b are located on a side of the data signal transmission lines 202a facing away from the substrate 10. The data signal connection lines 202b may be electrically connected to the driver chip located in the bending region BB1, and the data signal transmission lines 202a may be electrically connected to the pixel circuit located in the display region AA. The data signal transmission lines 202a and the data signal connection lines 202b are electrically connected through at least one connection via S1 in the data line via transition region BB22 to disperse the bending stress experienced by the bending region BB1 when bent. The first shielding structure 310 includes a data shielding structure section 310b, and the data shielding structure section 310b at least partially overlaps with the data line via transition region BB22 in the thickness direction of the display panel. Thus, the data shielding structure section 310b blocks reactive ions from reaching the connection via S1 in the data line via transition region BB22, and the reactive ions are prevented from reacting with the material of the connection via S1 in the data line via transition region BB22 and corroding the connection via S1, thereby alleviating the corrosion phenomenon in the data line via transition region BB22 and improving the display performance of the display panel.

On the basis of the preceding embodiments, still referring to FIG. 7, the gate shielding structure section 310a and the data shielding structure section 310b are connected to the same potential signal line.

In an example, in the implementation shown in FIG. 7, both the gate shielding structure section 310a and the data shielding structure section 310b are electrically connected to the first power supply routing 510 to provide a negative fixed potential signal for the gate shielding structure section 310a and the data shielding structure section 310b through the first power supply routing 510, respectively. Thus, the gate shielding structure section 310a and the data shielding structure section 310b exert either repulsive or attractive forces on the reactive ions, thereby further reducing the number of reactive ions reaching the connection via S1 and alleviating the corrosion in the first via transition region BB2. It should be noted that FIG. 7 merely illustrates an example where both the gate shielding structure section 310a and the data shielding structure section 310b are electrically connected to the first power supply routing 510, but the present application is not limited thereto. In other embodiments, the gate shielding structure section 310a and the data shielding structure section 310b may also be electrically connected to the second power supply routing 520 to provide a positive fixed potential signal for the gate shielding structure section 310a and the data shielding structure section 310b through the second power supply routing 520, respectively.

In another embodiment, still referring to FIG. 10, the gate shielding structure section 310a and the data shielding structure section 310b are independently provided, and the gate shielding structure section 310a and the data shielding structure section 310b are connected to different potential signal lines.

In one or more embodiments, in the implementation shown in FIG. 10, the gate shielding structure section 310a and the data shielding structure section 310b are independently provided. The gate shielding structure section 310a is electrically connected to the first power supply routing 510 to provide a negative fixed potential signal for the gate shielding structure section 310a through the first power supply routing 510. The data shielding structure section 310b is electrically connected to the second power supply routing 520 to provide a positive fixed potential signal for the data shielding structure section 310b through the second power supply routing 520.

It should be understood that, in other embodiments, the gate shielding structure section 310a may also be set to be electrically connected to the second power supply routing 520, and the data shielding structure section 310b may also be set to be electrically connected to the first power supply routing 510. The present application is not limited thereto, and those skilled in the art may make corresponding configurations of the above connection relationship according to actual requirements.

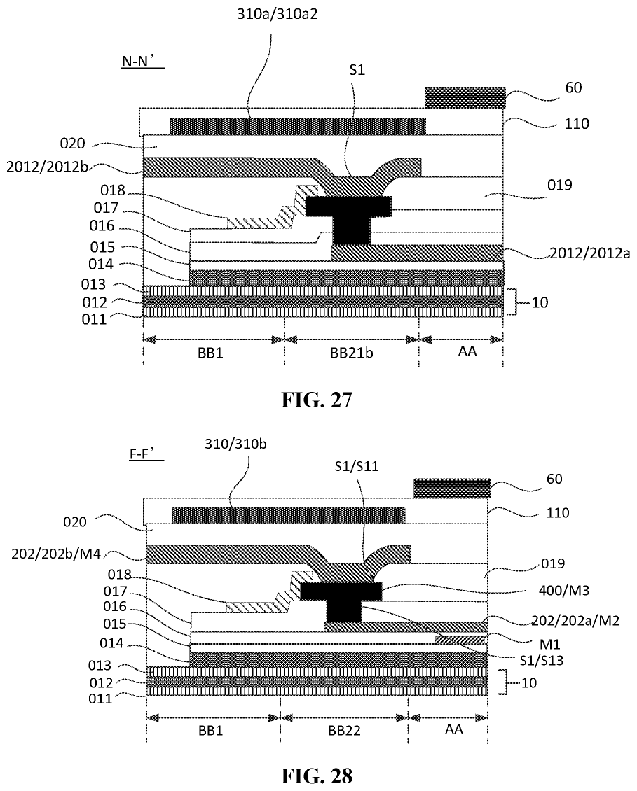

In one or more embodiments, on the basis of the preceding embodiments, FIG. 26 illustrates another section view taken along the direction M-M′ of the non-display region illustrated in FIG. 11, and FIG. 27 illustrates another section view taken along the direction N-N′ of the non-display region illustrated in FIG. 11. Referring to FIGS. 11, 26, and 27, the gate signal routing 201 includes a first gate signal routing 2011 and a second gate signal routing 2012, and a level of signals transmitted through the first gate signal routing 2011 is opposite to a level of signals transmitted through the second gate signal routing 2012. The gate line via transition region BB21 includes a first via transition sub-region BB21a and a second via transition sub-region BB21b. The first gate signal routing 2011 includes first gate signal transmission lines 2011a and first gate signal connection lines 2011b arranged in different layers. The first gate signal connection lines 2011b are located on a side of the first gate signal transmission lines 2011a facing away from the substrate 10. The first gate signal transmission lines 2011a and the first gate signal connection lines 2011b are electrically connected through at least one connection via S1 in the first via transition sub-region BB21a. The second gate signal routing 2012 includes second gate signal transmission lines 2012a and second gate signal connection lines 2012b arranged in different layers. The second gate signal connection lines 2012b are located on a side of the second gate signal transmission lines 2012a facing away from the substrate 10. The second gate signal transmission lines 2012a and the second gate signal connection lines 2012b are electrically connected through at least one connection via S1 in the second via transition sub-region BB21b. The gate shielding structure section 310a includes a first sub-shielding structure 310a1 and a second sub-shielding structure 310a2. In the thickness direction of the display panel, the first sub-shielding structure 310a1 at least partially overlaps with the first via transition sub-region BB21a, and the second sub-shielding structure 310a2 at least partially overlaps with the second via transition sub-region BB21b. A potential signal line connected to the first sub-shielding structure 310a1 is different from a potential signal line connected to the second sub-shielding structure 310a2.

In one or more embodiments, as shown in FIGS. 11 and 26, the gate signal routing 201 includes a first gate signal routing 2011 and a second gate signal routing 2012, and a level of signals transmitted through the first gate signal routing 2011 is opposite to a level of signals transmitted through the second gate signal routing 2012. For example, the first gate signal routing 2011 may transmit a fixed low-level signal, and the second gate signal routing 2012 may transmit a fixed high-level signal. The first gate signal routing 2011 includes first gate signal transmission lines 2011a and first gate signal connection lines 2011b arranged in different layers. The first gate signal connection lines 2011b are located on a side of the first gate signal transmission lines 2011a facing away from the substrate 10. The first gate signal connection lines 2011b may be electrically connected to the driver chip located in the bending region BB1, and the first gate signal transmission lines 2011a may be electrically connected to the gate driver circuit located in the left bezel region and/or the right bezel region to provide the fixed high-level signal for the gate driver circuit. The gate line via transition region BB21 includes a first via transition sub-region BB21a. The first gate signal transmission lines 2011a and the first gate signal connection lines 2011b are electrically connected through at least one connection via S1 in the first via transition sub-region BB21a. By arranging the first sub-shielding structure 310a1 to at least partially overlap with the first via transition sub-region BB21a in the thickness direction of the display panel, the first sub-shielding structure 310a1 blocks reactive ions from reaching the connection via S1 in the first via transition sub-region BB21a, thereby alleviating the corrosion phenomenon in the first via transition sub-region BB21a and improving the display performance of the display panel. Furthermore, the first sub-shielding structure 310a1 may be electrically connected to the first power supply routing 510 to provide a negative fixed potential signal for the first sub-shielding structure 310a1 through the first power supply routing 510, and the first sub-shielding structure 310a1 then exerts either repulsive or attractive forces on the reactive ions, thereby further reducing the number of reactive ions reaching the connection via S1 and alleviating the corrosion phenomenon in the first via transition sub-region BB21a.

Similarly, as shown in FIGS. 11 and 27, the second gate signal routing 2012 includes second gate signal transmission lines 2012a and second gate signal connection lines 2012b arranged in different layers. The second gate signal connection lines 2012b are located on a side of the second gate signal transmission lines 2012a facing away from the substrate 10. The second gate signal connection lines 2012b may be electrically connected to the driver chip located in the bending region BB1, and the second gate signal transmission lines 2012a may be electrically connected to the gate driver circuit located in the left bezel region and/or the right bezel region to provide a fixed low-level signal for the gate driver circuit. The gate line via transition region BB21 further includes a second via transition sub-region BB21b. The second gate signal transmission lines 2012a and the second gate signal connection lines 2012b are electrically connected through at least one connection via S1 in the second via transition sub-region BB21b. By arranging the second sub-shielding structure 310a2 to at least partially overlap with the second via transition sub-region BB21b in the thickness direction of the display panel, the second sub-shielding structure 310a2 blocks reactive ions from reaching the connection via S1 in the second via transition sub-region BB21b, thereby alleviating the corrosion phenomenon in the second via transition sub-region BB21b and improving the display performance of the display panel. Furthermore, the second sub-shielding structure 310a2 may be electrically connected to the second power supply routing 520 to provide a positive fixed potential signal for the second sub-shielding structure 310a2 through the second power supply routing 520, and the second sub-shielding structure 310a2 then exerts either repulsive or attractive forces on the reactive ions, thereby further reducing the number of reactive ions reaching the connection via S1 and alleviating the corrosion phenomenon in the first via transition sub-region BB21a.

It should be understood that since the signals transmitted by the first gate signal routing 2011 and the second gate signal routing 2012 are at opposite levels, different fixed potential signals may be provided for the first sub-shielding structure 310a1 arranged on the first gate signal routing 2011 and the second sub-shielding structure 310a2 arranged on the second gate signal routing 2012, respectively. In an example, in the implementation shown in FIG. 11, if the first gate signal routing 2011 transmits a fixed low-level signal, the first sub-shielding structure 310a1 is electrically connected to the first power supply routing 510 to provide a negative fixed potential signal for the first sub-shielding structure 310a1, thereby avoiding any influence of the first sub-shielding structure 310a1 on the signal transmitted by the first gate signal routing 2011. Similarly, if the second gate signal routing 2012 transmits a fixed high-level signal, the second sub-shielding structure 310a2 is electrically connected to the second power supply routing 520 to provide a positive fixed potential signal for the second sub-shielding structure 310a2, thereby avoiding any influence of the second sub-shielding structure 310a2 on the signal transmitted by the second gate signal routing 2012.

In one or more embodiments, on the basis of the preceding embodiments, still referring to FIG. 7, the first via transition region BB2 includes multiple connection vias, and the multiple connection vias are arranged in the second direction Y. The first shielding structure 310 extends in the second direction Y, and the second direction Y intersects the direction from the display region AA toward the bending region BB1.

In one or more embodiments, as shown in FIG. 7, the gate signal routing 201 and the data signal routing 202 extend in the first direction X and are arranged in the second direction Y, where the first direction X is the direction from the display region AA toward the bending region BB1, and the second direction Y intersects the first direction X. The gate line via transition region BB21 and the data line via transition region BB22 are arranged in the second direction Y in the first via transition region BB2, causing multiple connection vias in the first via transition region BB2 to be arranged in the second direction Y. On the basis of the above, by arranging the first shielding structure 310 to extend in the second direction Y, the first shielding structure 310 can simultaneously overlap with multiple connection vias in the thickness direction of the display panel, thereby ensuring a simple configuration of the first shielding structure 310.

In one or more embodiments, on the basis of the preceding embodiments, still referring to FIG. 14, the first shielding structure 310 further at least partially overlaps with the signal connection lines 220. In one or more embodiments, in the implementation shown in FIG. 14, the signal routing 20 includes a gate signal routing 201 and a data signal routing 202. Accordingly, the signal connection lines 220 include gate signal connection lines 201b and data signal connection lines 202b. Both the gate signal connection lines 201b and the data signal connection lines 202b are electrically connected to the driver chip located in the bending region BB1. By arranging the first shielding structure 310 to at least partially overlap with both the gate signal connection lines 201b and the data signal connection lines 202b in a thickness direction of the display panel, the first shielding structure 310 is also capable of providing a blocking function in a region of the bending region BB1 adjacent to a first via transition region BB2. As such, reactive ions are prevented from bypassing the first shielding structure 310 at a junction region between the first via transition region BB2 and the bending region BB1, thereby further enhancing a blocking effect of the first shielding structure 310.

In one or more embodiments, still referring to FIG. 15, the display panel further includes a second via transition region BB3. The second via transition region BB3 is located on a side of the bending region BB1 facing away from the first via transition region BB2. The display panel further includes a second shielding structure 320. In the thickness direction of the display panel, the second shielding structure 320 at least partially overlaps with the second via transition region BB3.

In one or more embodiments, as shown in FIG. 15, the second via transition region BB3 is located on a side of the bending region BB1 facing away from the first via transition region BB2, that is, the bending region BB1 is located between the second via transition region BB3 and the first via transition region BB2. Since the first shielding structure 310 is arranged above the first via transition region BB2, to balance the bending stress experienced by the bending region BB1 when bent, a second shielding structure 320 is provided above the second via transition region BB3, that is, in the thickness direction of the display panel, the second shielding structure 320 at least partially overlaps with the second via transition region BB3. It should be understood that since the second via transition region BB3 is located on a side of the bending region BB1 facing away from the first via transition region BB2, that is, the second via transition region BB3 is farther from the boundary of the display region AA, the elemental iodine released by the iodine-based polarizer layer in the display region AA has greater difficulty reaching the second via transition region BB3. Therefore, the corrosion phenomenon at the location of the second via transition region BB3 is less severe than the corrosion phenomenon at the first via transition region BB2.

In one or more embodiments, on the basis of the preceding embodiments, still referring to FIG. 16, the display region AA further includes data signal lines 200 and signal wirings 300. The data signal lines 200 include first data signal lines 200a and second data signal lines 200b. The display region AA includes a first display region AA1 and a second display region AA2. The second display region AA2 is located on both sides of the first display region AA1 in the second direction Y, where the second direction Y intersects the direction from the display region AA toward the bending region BB1. The first data signal lines 200a are located in the second display region AA2, and the second data signal lines 200b are located in the first display region AA1. The first data signal lines 200a are electrically connected to data signal transmission lines 202a in the first via transition region BB2 through the signal wirings 300. The second data signal lines 200b are electrically connected to the data signal transmission lines 202a in the first via transition region BB2. The signal wirings 300 include a first signal wiring 300a and a second signal wiring 300b connected to each other. The extending direction of the first signal wiring 300a intersects the extending direction of the second signal wiring 300b.

In one or more embodiments, as shown in FIG. 16, the display region AA includes a first display region AA1 and a second display region AA2. The second display region AA2 is located on both sides of the first display region AA1 in the second direction Y. Compared to the first display region AA1, the second display region AA2 is closer to the boundary of the display region AA. Furthermore, the display region AA includes first data signal lines 200a and second data signal lines 200b. The first data signal lines 200a are located in the second display region AA2, that is, at the boundary of the display region AA. The first via transition region BB2 includes a data signal routing 202, and the data signal routing 202 includes data signal transmission lines 202a and data signal connection lines 202b. The data signal connection lines 202b are electrically connected to the driver chip in the bending region BB1, and the data signal transmission lines 202a are electrically connected to either the first data signal lines 200a or the second data signal lines 200b in the display region AA, so that the driver chip transmits a data signal to the first data signal lines 200a or the second data signal lines 200b in the display region AA. On the basis of the above, the first data signal lines 200a are electrically connected to the data signal transmission lines 202a in the first via transition region BB2 through a first signal wiring 300a and a second signal wiring 300b, whose extension directions intersect. The second data signal lines 200b are directly electrically connected to the data signal transmission lines 202a in the first via transition region BB2. Thus, the routing of all the data signal lines 200 is centralized in the central region of the display region AA, thereby facilitating the reduction of the width of the bending region BB1 in the second direction Y.

In one or more embodiments, on the basis of the preceding embodiments, still referring to FIG. 25, the display panel further includes a first metal layer M1, a third metal layer M3, and a fourth metal layer M4 that are arranged in a stacked manner on a side of the substrate 10. The signal routing 20 includes a data signal routing 202. The data signal routing 202 includes data signal transmission lines 202 a data signal transmission lines 202a and data signal connection lines 202b. The data signal transmission lines 202a are located in the first metal layer M1, and the data signal connection lines 202b are located in the fourth metal layer M4. The display panel further includes a first bridging structure 400. The first bridging structure 400 is located in the third metal layer M3. The connection vias S1 include a first connection via S11 and a second connection via S12. In the thickness direction of the display panel, the first connection via S11 at least partially overlaps with the second connection via S12 so that the first connection via S11 communicates with the second connection via S12 through the first bridging structure 400. The data signal connection lines 202b are electrically connected to the first bridging structure 400 through the first connection via S11, and the first bridging structure 400 is electrically connected to the data signal transmission lines 202a through the second connection via S12. Thus, the electrical connection between the data signal transmission lines 202a located in the first metal layer M1 and the data signal connection lines 202b located in the fourth metal layer M4 is achieved through the first bridging structure 400, the first connection via S11, and the second connection via S12, thereby ensuring a simple connection between the data signal transmission lines 202a and the data signal connection lines 202b.

It should be understood that a second metal layer M2 may also be included between the first metal layer M1 and the third metal layer M3. Since the data signal transmission lines 202a are electrically connected to the data signal lines in the display region and the data signal lines is typically located in the first metal layer M1 or the second metal layer M2, the data signal transmission lines 202a in the first via transition region BB2 may be located in either the first metal layer M1 or the second metal layer M2. In other embodiments, FIG. 28 illustrates yet another section view taken along the direction F-F′ of the non-display region illustrated in FIG. 7. Referring to FIG. 28, the display panel includes a first metal layer M1, a second metal layer M2, a third metal layer M3, and a fourth metal layer M4 that are arranged in a stacked manner on a side of the substrate 10. The signal routing 20 includes a data signal routing 202. The data signal routing 202 includes data signal transmission lines 202a and data signal connection lines 202b. The data signal transmission lines 202a are located in the second metal layer M2, and the data signal connection lines 202b are located in the fourth metal layer M4. The display panel further includes a first bridging structure 400. The first bridging structure 400 is located in the third metal layer M3. The connection vias S1 include a first connection via S11 and a third connection via S13. In the thickness direction of the display panel, the first connection via S11 at least partially overlaps with the third connection via S13 so that the first connection via S11 communicates with the third connection via S13 through the first bridging structure 400. The data signal connection lines 202b are electrically connected to the first bridging structure 400 through the first connection via S11, and the first bridging structure 400 is electrically connected to the data signal transmission lines 202a through the third connection via S13. Thus, the electrical connection between the data signal transmission lines 202a located in the second metal layer M2 and the data signal connection lines 202b located in the fourth metal layer M4 is achieved through the first bridging structure 400, the first connection via S11, and the third connection via S13, thereby ensuring a simple connection between the data signal transmission lines 202a and the data signal connection lines 202b.

It should be noted that a second buffer layer 014 and a gate insulating layer 015 may also be included between the substrate 10 and the first metal layer M1. The second buffer layer 014 is located on a side of the gate insulating layer 015 facing the substrate 10, and the first metal layer M1 is disposed on the gate insulating layer 015. Additionally, multiple interlayer insulating layers are provided between the fourth metal layer M4 and the first metal layer M1, such as a first interlayer insulating layer 016 and a second interlayer insulating layer 017. The first interlayer insulating layer 016 is located on a side of the second interlayer insulating layer 017 facing the substrate 10. The first bridging structure 400 penetrates through at least part of the interlayer insulating layers. In the implementation shown in FIG. 9, the first bridging structure 400 penetrates through the second interlayer insulating layer 017 and part of the first interlayer insulating layer 016. In the implementation shown in FIG. 17, the first bridging structure 400 penetrates through part of the second interlayer insulating layer 017. Furthermore, the display panel further includes a passivation layer 018 covering part of the second interlayer insulating layer 017 and part of the first bridging structure 400. That is, the first connection via S11 and the second connection via S12, or the first connection via S11 and the third connection via S13, connected by the first bridging structure 400 are covered by the interlayer insulating layers and the passivation layer 018, thereby avoiding erosion from reactive ions. It should be understood that a dielectric layer 019 is also disposed between the substrate 10 and the fourth metal layer M4. The dielectric layer 019 serves functions such as signal isolation, parasitic capacitance control, and stress buffering. Moreover, a planarization layer 020 is also provided on a side of the fourth metal layer M4 facing away from the substrate 10. The planarization layer 020 optimizes film layer flatness, thereby providing a foundation for subsequent device fabrication.

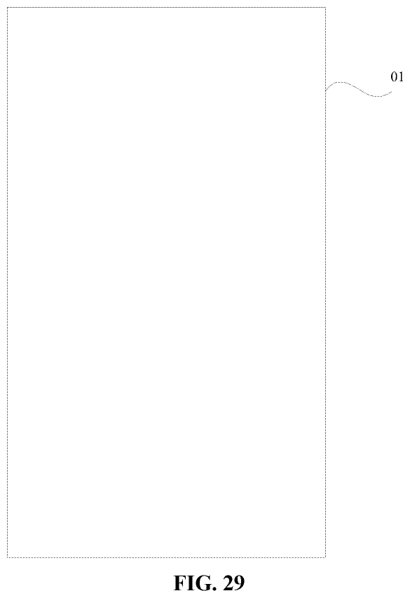

Based on the same inventive concept, an embodiment of the present application further provides a display device. FIG. 29 illustrates a structure diagram of a display device according to an embodiment of the present application. As shown in FIG. 29, the display device includes the display panel 01 in any one of the preceding embodiments. Therefore, the display device provided by the embodiment of the present application here has the beneficial effects of the display panel 01 provided by the embodiments of the present application, and the details are not repeated here. In an example, the display device may be an electronic device such as a mobile phone, a computer, a smart wearable device (for example, a smartwatch), or an in-vehicle display device.

It should be noted that the preceding are preferred embodiments of the present application and technical principles used therein. It should be understood by those skilled in the art that the present application is not limited to the embodiments described herein. Those skilled in the art can make various apparent variations, adaptations, and substitutions without departing from the scope of the present application. Therefore, although the present application has been described in detail through the preceding embodiments, the present application is not limited to the preceding embodiments and may include other equivalent embodiments without departing from the concept of the present application. The scope of the present application is determined by the scope of the appended claims.

What is claimed is:

1. A display panel, comprising a display region and a non-display region,
wherein the non-display region is located on at least one side of the display region,
the non-display region comprises a bending region and a first via transition region, and
the first via transition region is located on a side of the bending region facing the display region;
wherein the display panel further comprises a substrate and a signal routing located on a side of the substrate,
the signal routing comprises signal transmission lines and signal connection lines arranged in different layers,
the signal connection lines are located on a side of the signal transmission lines facing away from the substrate, and
the signal transmission lines and the signal connection lines are electrically connected through at least one connection via in the first via transition region; and
wherein the display panel further comprises a first shielding structure,
the first shielding structure is located on a side of the signal connection lines facing away from the substrate, and
in a thickness direction of the display panel, the first shielding structure at least partially overlaps with the first via transition region.

2. The display panel according to claim 1, wherein the first shielding structure is electrically connected to a potential signal line.

3. The display panel according to claim 2, wherein the potential signal line is a fixed potential signal line.

4. The display panel according to claim 3, wherein the display panel further comprises an iodine-based polarizer layer located on a side of the first shielding structure facing away from the substrate;
wherein the display panel further comprises a power supply routing located on a side of the substrate,
the power supply routing comprises a first power supply routing electrically connected to the first shielding structure, and
the first power supply routing is arranged to provide a negative fixed potential signal for the first shielding structure.

5. The display panel according to claim 3, wherein the display panel further comprises an iodine-based polarizer layer located on a side of the first shielding structure facing away from the substrate; and
wherein the display panel further comprises a power supply routing located on a side of the substrate,
the power supply routing comprises a second power supply routing electrically connected to the first shielding structure, and
the second power supply routing is arranged to provide a positive fixed potential signal for the first shielding structure.

6. The display panel according to claim 1, wherein the first shielding structure comprises a first shielding layer; and
wherein the display panel further comprises a pixel defining layer, and
the first shielding layer is located between a film layer where the signal connection lines are located and a film layer where the pixel defining layer is located.

7. The display panel according to claim 6, wherein the display panel further comprises a light-emitting element,
the light-emitting element comprises a first electrode, and
an opening in the pixel defining layer is arranged to expose at least a portion of the first electrode; and
wherein the first electrode is located in the display region, and
a film layer where the first electrode is located is located between the film layer where the signal connection lines are located and the film layer where the pixel defining layer is located; and
wherein the first shielding structure is disposed in a same layer as the first electrode and is insulated from the first electrode.

8. The display panel according to claim 1, wherein the display panel further comprises a silicon-nitride-based inorganic layer located on a side of the signal connection lines facing away from the substrate, and
the silicon-nitride-based inorganic layer is staggered from the first via transition region in a thickness direction of the display panel.

9. The display panel according to claim 1, wherein the signal routing comprises a gate signal routing and a data signal routing, and
the first via transition region comprises a gate line via transition region and a data line via transition region,
wherein the gate signal routing comprises gate signal transmission lines and gate signal connection lines arranged in different layers,
the gate signal connection lines are located on a side of the gate signal transmission lines facing away from the substrate, and
the gate signal transmission lines and the gate signal connection lines are electrically connected through at least one connection via in the gate line via transition region;
wherein the data signal routing comprises data signal transmission lines and data signal connection lines arranged in different layers,
the data signal connection lines are located on a side of the data signal transmission lines facing away from the substrate, and
the data signal transmission lines and the data signal connection lines are electrically connected through at least one connection via in the data line via transition region; and
wherein the first shielding structure comprises a gate shielding structure section and a data shielding structure section, and
in a thickness direction of the display panel, the gate shielding structure section at least partially overlaps with the gate line via transition region and the data shielding structure section at least partially overlaps with the data line via transition region.

10. The display panel according to claim 9, wherein the gate shielding structure section and the data shielding structure section are connected to a same potential signal line.

11. The display panel according to claim 9, wherein the gate shielding structure section and the data shielding structure section are independently provided, and the gate shielding structure section and the data shielding structure section are connected to different potential signal lines.

12. The display panel according to claim 11, wherein the gate signal routing comprises a first gate signal routing and a second gate signal routing, and a level of signals transmitted through the first gate signal routing is opposite to a level of signals transmitted through the second gate signal routing;
wherein the gate line via transition region comprises a first via transition sub-region and a second via transition sub-region;
wherein the first gate signal routing comprises first gate signal transmission lines and first gate signal connection lines arranged in different layers, the first gate signal connection lines are located on a side of the first gate signal transmission lines facing away from the substrate, and the first gate signal transmission lines and the first gate signal connection lines are electrically connected through at least one connection via in the first via transition sub-region;
wherein the second gate signal routing comprises second gate signal transmission lines and second gate signal connection lines arranged in different layers,
the second gate signal connection lines are located on a side of the second gate signal transmission lines facing away from the substrate, and
the second gate signal transmission lines and the second gate signal connection lines are electrically connected through at least one connection via in the second via transition sub-region; and
wherein the gate shielding structure section comprises a first sub-shielding structure and a second sub-shielding structure;
in the thickness direction of the display panel, the first sub-shielding structure at least partially overlaps with the first via transition sub-region, and the second sub-shielding structure at least partially overlaps with the second via transition sub-region; and
a potential signal line connected to the first sub-shielding structure is different from a potential signal line connected to the second sub-shielding structure.

13. The display panel according to claim 1, wherein the first via transition region comprises a plurality of connection vias, and the plurality of connection vias are arranged in a second direction; and
the first shielding structure extends in the second direction intersecting a direction from the display region toward the bending region.

14. The display panel according to claim 1, wherein in a thickness direction of the display panel, the first shielding structure at least partially overlaps with the signal connection lines.

15. The display panel according to claim 1, wherein the display panel further comprises a second via transition region; and
the second via transition region is located on a side of the bending region facing away from the first via transition region; and
wherein the display panel further comprises a second shielding structure; and
in a thickness direction of the display panel, the second shielding structure at least partially overlaps with the second via transition region.

16. The display panel according to claim 1, wherein the display region further comprises data signal lines and signal wirings;
the data signal lines comprise first data signal lines and second data signal lines, the display region comprises a first display region and a second display region, and the second display region is located on both sides of the first display region in a second direction intersecting a direction from the display region toward the bending region;
the first data signal lines are located in the second display region, and the second data signal lines are located in the first display region;
the first data signal lines are electrically connected to the data signal transmission lines in the first via transition region through the signal wirings;
the second data signal lines are electrically connected to the data signal transmission lines in the first via transition region directly; and
the signal wirings comprises a first signal wiring and a second signal wiring connected to each other, and an extending direction of the first signal wiring intersects an extending direction of the second signal wiring.

17. The display panel according to claim 1, wherein the display panel further comprises a first metal layer, a third metal layer, and a fourth metal layer that are arranged in a stacked manner on a side of the substrate,
the signal routing comprises a data signal routing, and the data signal routing comprises data signal transmission lines and data signal connection lines;
the data signal transmission lines are located in the first metal layer, the data signal connection lines are located in the fourth metal layer, and the display panel further comprises a first bridging structure located in the third metal layer;
the at least one connection via comprises a first connection via and a second connection via, and in a thickness direction of the display panel, the first connection via at least partially overlaps with the second connection via; and
the data signal connection lines are electrically connected to the first bridging structure through the first connection via, and the first bridging structure is electrically connected to the data signal transmission lines through the second connection via.

18. The display panel according to claim 1, wherein
the display panel further comprises a second metal layer, a third metal layer, and a fourth metal layer that are arranged in a stacked manner on a side of the substrate,
the signal routing comprises a data signal routing, and the data signal routing comprises data signal transmission lines and data signal connection lines, and
the data signal transmission lines are located in the second metal layer, and the data signal connection lines are located in the fourth metal layer; and
wherein the display panel further comprises a first bridging structure located in the third metal layer,
the at least one connection via comprises a first connection via and a third connection via,
in a thickness direction of the display panel, the first connection via at least partially overlaps with the third connection via,
the data signal connection lines are electrically connected to the first bridging structure through the first connection via, and
the first bridging structure is electrically connected to the data signal transmission lines through the third connection via.

19. A display panel, comprising a display region and a non-display region,
wherein the non-display region is located on at least one side of the display region,
the non-display region comprises a bending region and a first via transition region, and
the first via transition region is located on a side of the bending region facing the display region;
wherein the display panel further comprises a substrate and a signal routing located on a side of the substrate,
the signal routing comprises signal transmission lines and signal connection lines arranged in different layers,
the signal connection lines are located on a side of the signal transmission lines facing away from the substrate, and
the signal transmission lines and the signal connection lines are electrically connected through at least one connection via in the first via transition region;
wherein the display panel further comprises a first shielding structure,
the first shielding structure is located on a side of the signal connection lines facing away from the substrate, and
the first shielding structure at least partially overlaps with the first via transition region;
wherein the first shielding structure comprises a second shielding layer; and
wherein the display panel further comprises a pixel defining layer, and
the second shielding layer is located on a side of the pixel defining layer facing away from the substrate.

20. The display panel according to claim 19, wherein
the display panel further comprises at least one touch metal layer;
the at least one touch metal layer is located on a side of the pixel defining layer facing away from the substrate; and
the second shielding layer is disposed in a same layer as the at least one touch metal layer and is insulated from the at least one touch metal layer.

21. The display panel according to claim 20, wherein
the display panel further comprises a silicon-nitride-based inorganic layer located on a side of the signal connection lines facing away from the substrate;
the at least one touch metal layer comprises a first touch metal layer and a second touch metal layer, the silicon-nitride-based inorganic layer comprises a first inorganic layer and a second inorganic layer, the first inorganic layer is located on a side of the second inorganic layer facing the substrate, the first touch metal layer is located between the first inorganic layer and the second inorganic layer, and the second touch metal layer is located on a side of the silicon-nitride-based inorganic layer facing away from the substrate; and
in a thickness direction of the display panel, the first touch metal layer covers the first inorganic layer, and the second touch metal layer covers the silicon-nitride-based inorganic layer; and
wherein the display panel comprises at least one of the following:
the second shielding layer is disposed in a same layer as the first touch metal layer and is insulated from the first touch metal layer, or
the second shielding layer is disposed in a same layer as the second touch metal layer and is insulated from the second touch metal layer.

22. A display panel, comprising a display region and a non-display region,
wherein the non-display region is located on at least one side of the display region,
the non-display region comprises a bending region and a first via transition region, and
the first via transition region is located on a side of the bending region facing the display region;
wherein the display panel further comprises a substrate and a signal routing located on a side of the substrate,
the signal routing comprises signal transmission lines and signal connection lines arranged in different layers,
the signal connection lines are located on a side of the signal transmission lines facing away from the substrate, and
the signal transmission lines and the signal connection lines are electrically connected through at least one connection via in the first via transition region; and
wherein the display panel further comprises a silicon-nitride-based inorganic layer located on a side of the signal connection lines facing away from the substrate, and
the silicon-nitride-based inorganic layer is staggered from the first via transition region in a thickness direction of the display panel.

23. The display panel according to claim 22, wherein the display panel further comprises a first shielding structure, the first shielding structure is located on a side of the signal connection lines facing away from the substrate, and the first shielding structure at least partially overlaps with the first via transition region.

24. The display panel according to claim 23, wherein the first shielding structure is electrically connected to a potential signal line.

25. The display panel according to claim 24, wherein the potential signal line is a fixed potential signal line.

26. The display panel according to claim 25, wherein the display panel further comprises an iodine-based polarizer layer located on a side of the silicon-nitride-based inorganic layer facing away from the substrate; and
wherein the display panel further comprises a power supply routing located on a side of the substrate,
the power supply routing comprises a first power supply routing,
the first shielding structure is electrically connected to the first power supply routing, and
the first power supply routing is arranged to provide a negative fixed potential signal for the first shielding structure.

27. The display panel according to claim 25, wherein
the display panel further comprises an iodine-based polarizer layer located on a side of the silicon-nitride-based inorganic layer facing away from the substrate; and
wherein the display panel further comprises a power supply routing located on a side of the substrate,
the power supply routing comprises a second power supply routing,
the first shielding structure is electrically connected to the second power supply routing, and
the second power supply routing is arranged to provide a positive fixed potential signal for the first shielding structure.

28. The display panel according to claim 23, wherein the first shielding structure comprises a first shielding layer; and
wherein the display panel further comprises a pixel defining layer, and the first shielding layer is located between a film layer where the signal connection lines are located and a film layer where the pixel defining layer is located.

29. The display panel according to claim 28, wherein the display panel further comprises a light-emitting element, the light-emitting element comprises a first electrode, and an opening in the pixel defining layer is arranged to expose at least a portion of the first electrode;
wherein the first electrode is located in the display region, and a film layer where the first electrode is located is located between the film layer where the signal connection lines are located and the film layer where the pixel defining layer is located; and
wherein the first shielding structure is disposed in a same layer as the first electrode and is insulated from the first electrode.

30. The display panel according to claim 23, wherein
the first shielding structure comprises a second shielding layer,
the display panel further comprises a pixel defining layer, and
the second shielding layer is located on a side of the pixel defining layer facing away from the substrate.

31. The display panel according to claim 30, wherein
the display panel further comprises at least one touch metal layer,
the at least one touch metal layer is located on a side of the pixel defining layer facing away from the substrate, and
the second shielding layer is disposed in a same layer as the at least one touch metal layer.

32. The display panel according to claim 23, wherein
the signal routing comprises a gate signal routing and a data signal routing,
the first via transition region comprises a gate line via transition region and a data line via transition region,
the gate signal routing comprises gate signal transmission lines and gate signal connection lines arranged in different layers,
the gate signal connection lines are located on a side of the gate signal transmission lines facing away from the substrate, and
the gate signal transmission lines and the gate signal connection lines are electrically connected through at least one connection via in the gate line via transition region; and
wherein the data signal routing comprises data signal transmission lines and data signal connection lines arranged in different layers,
the data signal connection lines are located on a side of the data signal transmission lines facing away from the substrate, and
the data signal transmission lines and the data signal connection lines are electrically connected through at least one connection via in the data line via transition region; and
wherein the first shielding structure comprises a gate shielding structure section and a data shielding structure section, and
in the thickness direction of the display panel, the gate shielding structure section at least partially overlaps with the gate line via transition region and the data shielding structure section at least partially overlaps with the data line via transition region.

33. The display panel according to claim 32, wherein the gate shielding structure section and the data shielding structure section are connected to a same potential signal line.

34. The display panel according to claim 32, wherein
the gate shielding structure section and the data shielding structure section are independently provided, and
the gate shielding structure section and the data shielding structure section are connected to different potential signal lines.

35. The display panel according to claim 34, wherein
the gate signal routing comprises a first gate signal routing and a second gate signal routing, and
a level of signals transmitted through the first gate signal routing is opposite to a level of signals transmitted through the second gate signal routing;
wherein the gate line via transition region comprises a first via transition sub-region and a second via transition sub-region;
the first gate signal routing comprises first gate signal transmission lines and first gate signal connection lines arranged in different layers,
the first gate signal connection lines are located on a side of the first gate signal transmission lines facing away from the substrate, and
the first gate signal transmission line and the first gate signal connection line are electrically connected through at least one connection via in the first via transition sub-region;
wherein the second gate signal routing comprises second gate signal transmission lines and second gate signal connection lines arranged in different layers,
the second gate signal connection lines are located on a side of the second gate signal transmission lines facing away from the substrate, and
the second gate signal transmission line and the second gate signal connection line are electrically connected through at least one connection via in the second via transition sub-region; and
wherein the gate shielding structure section comprises a first sub-shielding structure and a second sub-shielding structure,
in the thickness direction of the display panel, the first sub-shielding structure at least partially overlaps with the first via transition sub-region and the second sub-shielding structure at least partially overlaps with the second via transition sub-region, and
a potential signal connected to the first sub-shielding structure is different from a potential signal connected to the second sub-shielding structure.

36. The display panel according to claim 23, wherein
the first via transition region comprises a plurality of connection vias, and the plurality of connection vias are arranged in a second direction; and
the first shielding structure extends in the second direction intersecting a direction from the display region toward the bending region.

37. The display panel according to claim 23, wherein in the thickness direction of the display panel, the first shielding structure at least partially overlaps with the signal connection lines.

38. The display panel according to claim 23, wherein
the bending region further comprises a second via transition region;
the second via transition region is located on a side of the bending region facing away from the first via transition region;
the display panel further comprises a second shielding structure; and
in the thickness direction of the display panel, the second shielding structure at least partially overlaps with the second via transition region.

39. The display panel according to claim 22, wherein
the display region further comprises data signal lines and signal wirings, and
the data signal lines comprise first data signal lines and second data signal lines,
wherein the display region comprises a first display region and a second display region,
the second display region is located on both sides of the first display region in a second direction intersecting a direction from the display region toward the bending region,
the first data signal lines are located in the second display region, and
the second data signal lines are located in the first display region; and
wherein the first data signal lines are electrically connected to data signal transmission lines in the first via transition region through the signal wirings, and
the second data signal lines are electrically connected to data signal transmission lines in the first via transition region directly, and
wherein the signal wiring comprises a first signal wiring and a second signal wiring connected to each other, and
an extending direction of the first signal wiring intersects an extending direction of the second signal wiring.

40. The display panel according to claim 22, wherein
the display panel further comprises a first metal layer, a third metal layer, and a fourth metal layer that are arranged in a stacked manner on a side of the substrate;
the signal routing comprises a data signal routing, and the data signal routing comprises data signal transmission lines and data signal connection lines;
the data signal transmission lines are located in the first metal layer, the data signal connection lines are located in the fourth metal layer, and the display panel further comprises a first bridging structure located in the third metal layer;
the at least one connection via comprises a first connection via and a second connection via, and in the thickness direction of the display panel, the first connection via at least partially overlaps with the second connection via; and
the data signal connection lines are electrically connected to the first bridging structure through the first connection via, and the first bridging structure is electrically connected to the data signal transmission line through the second connection via.

41. The display panel according to claim 22, wherein
the display panel further comprises a second metal layer, a third metal layer, and a fourth metal layer that are arranged in a stacked manner on a side of the substrate;
the signal routing comprises a data signal routing, and the data signal routing comprises data signal transmission lines and data signal connection lines;
the data signal transmission lines are located in the second metal layer, the data signal connection lines are located in the fourth metal layer, and
the display panel further comprises a first bridging structure located in the third metal layer;
the at least one connection via comprises a first connection via and a third connection via, and in the thickness direction of the display panel, the first connection via at least partially overlaps with the third connection via; and
the data signal connection lines are electrically connected to the first bridging structure through the first connection via, and the first bridging structure is electrically connected to the data signal transmission line through the third connection via.
